(19) United States
(12) Patent Application Publication
(10) Pub. No.: US 2026/0164951 A1
(43) Pub. Date: Jun. 11, 2026

(54) DISPLAY DEVICE

(71) Applicant: LG Display Co., Ltd., Seoul (KR)

(72) Inventors: Junhyeok LEE, Paju-si (KR); Jungeun LEE, Paju-si (KR); HwanKeon LEE, Paju-si (KR); Jeongbeom LEE, Paju-si (KR)

(73) Assignee: LG Display Co., Ltd., Seoul (KR)

(21) Appl. No.: 19/255,388

(22) Filed: Jun. 30, 2025

(30) Foreign Application Priority Data
Dec. 10, 2024 (KR) 10-2024-0182853

(51) Int. Cl. H10K 59/124; H10K 59/80

(52) U.S. Cl. CPC H10K 59/124; H10K 59/80521

(57) ABSTRACT

The present disclosure provides a display device including a substrate with a display area configured to display an image. The display area includes a first display area having a transmissive area and a first non-transmissive area with a plurality of light emitting areas, and a second display area having a second non-transmissive area disposed outside the first display area. A pixel electrode is disposed in the first display area on the substrate, with an emission layer disposed on the pixel electrode. A common electrode is disposed on the emission layer and includes a plurality of holes located in the transmissive area. A black planarization layer is disposed between the substrate and the pixel electrode and is located in all or part of the first display area. This structure enables light transmission through designated regions while maintaining display performance and supporting sensor integration beneath the panel.

### CROSS-REFERENCE TO RELATED APPLICATION

This application claims priority from Korean Patent Application No. 10-2024-0182853, filed on Dec. 10, 2024 in the Korean Intellectual Property Office, which is hereby incorporated by reference for all purposes as if fully set forth herein.

### BACKGROUND

### Technical Field

Embodiments of the present disclosure relate to a display device.

### Description of the Related Art

As technology advances, display devices are now capable of not only displaying and capturing images, but also providing various sensing features. To enable this, display devices need to be equipped with optoelectronic components, such as cameras and sensing devices, also referred to as light receivers or sensors.

Since the optoelectronic components must receive light from the front of the display device, they should be positioned in areas favorable for light reception. However, if cameras or sensors are exposed on the front surface, it may limit the front-side design and cause unexpected degradation in image quality depending on the structural configuration. Therefore, display devices that realize full-screen displays have been proposed, in which the optoelectronic components are placed beneath the display panel to receive light without being exposed on the front.

### BRIEF SUMMARY

The disclosed display device features a structure that integrates optoelectronic components such as cameras and infrared sensors beneath the display panel without compromising image quality or screen appearance. It includes transmissive areas with patterned openings in the common electrode, allowing light to pass through designated regions while maintaining a full-screen display. To address issues caused by ultraviolet exposure, such as gas generation and pixel shrinkage, the design uses a black planarization layer in areas above the sensors. This layer is selected for its transparency to infrared light and its resistance to ultraviolet light, helping to preserve image uniformity and extend the operational life of the display.

The device also differentiates the planarization layer materials by region, using black materials in areas aligned with sensors and non-black materials in other regions. This approach enhances sensor performance and reduces image degradation. Additionally, metal walls are used at the boundary between these materials to ensure precise separation during manufacturing. The overall configuration supports high-resolution image display while enabling reliable and efficient integration of optical sensing components.

One or more embodiments of the present disclosure may provide a display device having a structure that prevents electronic components from being exposed on the front surface while allowing sensing devices placed beneath the display panel to properly receive light.

One or more embodiments of the present disclosure may provide a display device that prevents image quality degradation caused by a structure that enhances light transmittance.

One or more embodiments of the present disclosure may provide a display device that prevents image quality degradation in a sensor area even when exposed to ultraviolet light.

One or more embodiments of the present disclosure may provide a display device that prevents out-gassing and pixel shrinkage in a display area even when exposed to ultraviolet light.

Aspects, examples, and embodiments for solving issues or problems in the present disclosure are not limited to the foregoing description, and aspects, examples, and embodiments for solving other issues or problems will become apparent to those skilled in the art from the following description.

According to one or more embodiments of the present disclosure, a display device can be provided that includes a substrate including a display area formed on the substrate and configured to display an image, the display area including a first display area having a transmissive area and a first non-transmissive area that comprises a plurality of light emitting areas, and a second display area having a second non-transmissive area and disposed outside the first display area, a pixel electrode disposed in the first display area on the substrate, an emission layer disposed on the pixel electrode, a common electrode disposed on the emission layer and having a plurality of holes located in the transmissive area, and a black planarization layer disposed between the substrate and the pixel electrode, and located in an entire or partial portion of the first display area.

According to one or more embodiments of the present disclosure, a display device can be provided that includes a substrate including a display area formed on the substrate and configured to display an image, the display area including a first display area having a transmissive area and a first non-transmissive area that comprises a plurality of light emitting areas, and a second display area having a second non-transmissive area and disposed outside the first display area, a pixel electrode disposed in the first display area on the substrate, an emission layer disposed on the pixel electrode, a common electrode disposed on the emission layer and having a plurality of holes located in the transmissive area, and a planarization layer disposed between the substrate and the pixel electrode. In one or more aspects, the planarization layer may comprise a first part disposed in an entire or partial region of the first display area, and a second part different from the first part, and the first part and the second part may include different materials.

According to one or more embodiments of the present disclosure, a display device can be provided that includes a substrate including a display area formed on the substrate and configured to display an image, the display area including a first display area having a first transmissive area and a first non-transmissive area that comprises a plurality of light emitting areas, and a second display area having a second non-transmissive area and disposed outside the first display area, a pixel electrode disposed in the first display area on the substrate, an emission layer disposed on the pixel electrode, a common electrode disposed on the emission layer and having a plurality of holes located in the transmissive area, and a planarization layer disposed between the substrate and the pixel electrode. In one or more aspects, the planarization layer may be disposed between the substrate and the pixel electrode, and the planarization layer may include openings overlapping the plurality of holes.

According to one or more embodiments of the present disclosure, a display device may be provided that prevents electronic devices from being exposed on the front surface while allowing detection sensors placed beneath the display panel to properly receive light.

According to one or more embodiments of the present disclosure, a display device may be provided that prevents image quality degradation caused by a structure that enhances light transmittance.

According to one or more embodiments of the present disclosure, a display device may be provided that prevents out-gassing and pixel shrinkage in the display area even when exposed to ultraviolet light.

According to one or more embodiments of the present disclosure, a display device may be provided that prevents image quality degradation in the sensor area even when exposed to ultraviolet light.

According to one or more embodiments of the present disclosure, a display device may be provided that prevents pixel shrinkage even when exposed to ultraviolet light, thereby enabling the light emitting device to have a longer lifespan and operate at lower power.

Effects or advantages according to aspects, examples, and embodiments of the present disclosure are not limited to the foregoing description, and other effects or advantages will become apparent to those skilled in the art from the following description.

Aspects, examples, and embodiments discussed herein will be more fully understood from the detailed description and accompanying drawings provided below. It should be understood here that since alternative aspects, examples, and embodiments may add, omit, or change elements, structures, configurations, and the like, therefore, aspects, examples, and embodiments described herein are not meant to be limitations.

### BRIEF DESCRIPTION OF THE SEVERAL VIEWS OF THE DRAWINGS

The accompanying drawings, which are included to provide a further understanding of the disclosure and are incorporated in and constitute a part of the disclosure, illustrate aspects of the disclosure and together with the description serve to explain principles of the disclosure. In the drawings:

FIG. 1 illustrates an example display device according to embodiments of the present disclosure;

FIG. 2 illustrates a system configuration of an example display device according to embodiments of the present disclosure;

FIG. 3 illustrates an example configuration of display panel according to embodiments of the present disclosure;

FIG. 4 illustrates an example equivalent circuit of at least one subpixel included in a display device according to embodiments of the present disclosure;

FIG. 5 illustrates a first display area, a second display area and a third display area included in an example display panel according to embodiments of the present disclosure;

FIG. 6 illustrates an enlarged view of a first display area in an example display panel according to embodiments of the present disclosure;

FIG. 7 is an example cross-sectional view of a first display area in a display panel according to embodiments of the present disclosure;

FIG. 8 illustrates an ultraviolet reliability evaluation process of a display panel;

FIG. 9 illustrates a pixel shrinkage resulting from an ultraviolet reliability evaluation process of a display panel;

FIGS. 10 and 11 are example plan view and cross-sectional view of a first display area and a second display area in an example display panel having an infrared sensor performance improvement and pixel shrinkage prevention structure according to embodiments of the present disclosure;

FIG. 12 is an example cross-sectional view of a first display area, a second display area, and a third display area in a display panel according to embodiments of the present disclosure;

FIGS. 13 and 14 are example plan and cross-sectional views of a first display area and a second display area in a display panel according to embodiments of the present disclosure;

FIGS. 15 and 16 are example plan view and cross-sectional views of a first display area and a second display area in a display panel according to embodiments of the present disclosure;

FIG. 17 is an example plan view of a first display area and a second display area in a display panel according to embodiments of the present disclosure;

FIGS. 18 to 21 are example simplified cross-sectional views of a first display area in a display panel according to embodiments of the present disclosure;

FIG. 22 is an example plan view of a first display area and a second display area in a display panel according to embodiments of the present disclosure;

FIG. 23 is an example simplified cross-sectional view of a first display area and a second display area in a display panel according to embodiments of the present disclosure;

FIG. 24 illustrates a light transmittance of a display panel as a function of the wavelength of light passing through a first display area where a planarization layer comprising photoacrylic is disposed;

FIG. 25 illustrates a light transmittance of a display panel as a function of the wavelength of light passing through a first display area where a black planarization layer according to embodiments of the present disclosure is disposed;

FIG. 26 is an example plan view of a first display area and a second display area in a display panel according to embodiments of the present disclosure; and

FIG. 27 is an example simplified cross-sectional view of a first display area in a display panel according to embodiments of the present disclosure.

### DETAILED DESCRIPTION

Reference will now be made in detail to example embodiments of the present disclosure, examples or aspects of which may be illustrated in the accompanying drawings. In the following description, the structures, implementations, methods, and operations described herein are not limited to the specific examples, aspects, and embodiments set forth herein and may be changed as is known in the art, unless otherwise specified. Like reference numerals designate like elements throughout, unless otherwise specified. Names of the respective elements used in the following explanations are selected only for convenience of writing the specification and may thus be different from those used in actual products. Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure may be sufficiently thorough and complete to assist those skilled in the art to fully understand the scope of the present disclosure. In the following description, where the detailed description of the relevant known function or configuration may unnecessarily obscure embodiments of the present disclosure, a detailed description of such known function or configuration may be omitted.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Where the terms “comprise,” “have,” “include,” “contain,” “constitute,” “make up of,” “formed of,” and the like are used, one or more other elements may be added unless the term, such as “only,” is used. An element described in the singular form is intended to include a plurality of elements, and vice versa, unless the context clearly indicates otherwise.

Although the terms “first,” “second,” A, B, (a), (b), and the like may be used herein to describe various elements, these elements should not be interpreted to be limited by these terms as they are not used to define a particular order or precedence. These terms are used only to distinguish one element from another. For example, a first element could be termed a second element, and, similarly, a second element could be termed a first element, without departing from the scope of the present disclosure.

When it is mentioned that a first element “is connected or coupled to”, “contacts”, “overlaps with”, or the like a second element, it should be interpreted that, not only can the first element “be directly connected or coupled to”, “directly contact”, or “directly overlap with” the second element, but a third element can also be “interposed” between the first and second elements, or the first and second elements can “be connected or coupled to”, “contact”, “overlap with”, or the like each other via a fourth element. Here, the second element may be included in at least one of two or more elements that “are connected or coupled to”, “contact”, “overlap with”, or the like each other.

To elaborate, as used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

Where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third element or layer may be interposed therebetween. Furthermore, the terms “left,” “right,” “top,” “bottom, “downward,” “upward,” “upper,” “lower,” and the like refer to an arbitrary frame of reference.

In addition, when any dimensions, relative sizes, and the like are mentioned, it should be considered that numerical values for an elements or features, or corresponding information (e.g., level, range, and the like) include a tolerance or error range that may be caused by various factors (e.g., process factors, internal or external impact, noise, and the like) even when a relevant description is not specified. Further, the term “may” fully encompasses all the meanings of the term “can”.

Hereinafter, various example embodiments of the present disclosure will be described in detail with reference to the accompanying drawings. In addition, for convenience of description, a scale in which each of elements is illustrated in the accompanying drawings may differ from an actual scale. Thus, the illustrated elements are not limited to the specific scale in which they are illustrated in the drawings.

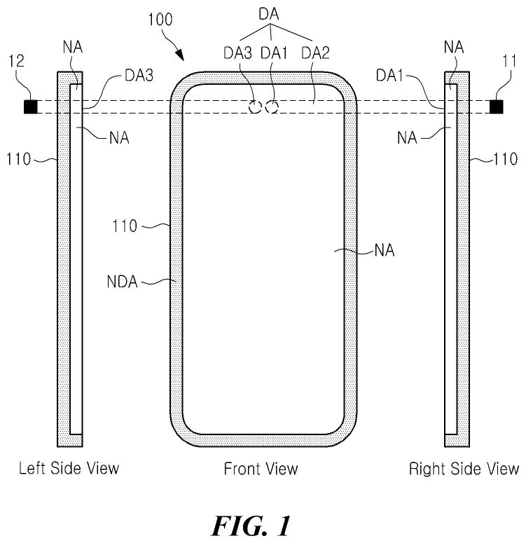

FIG. 1 illustrates an example display device 100 according to embodiments of the present disclosure.

Referring to FIG. 1, in one or more embodiments of the present disclosure, a display device 100 may include a display panel 110 and one or more electronic devices 11, 12.

The display panel 110 may include a display area DA in which image can be displayed and a non-display area NDA.

In the display area DA, a plurality of subpixels and signal lines for driving subpixels may be arranged.

The non-display area NDA may be an area outside the display area DA. Various signal lines may be disposed in the non-display area NDA, and various driving circuits may be connected. The non-display area NDA may be bent and not to be visible from the front surface or may be hidden by a case. The non-display area NDA may also be referred to as a bezel or bezel area.

The display area DA may include a first display area DA1, a second display area DA2, and a third display area DA3. An optical area OA may be included in the first display area DA1 and the third display area DA3, through which light may pass. A normal area NA may correspond to or be included in the second display area DA2, through which light may not pass.

Hereinafter, the normal area NA may also be referred to as the second display area DA2.

One or more electronic devices 11, 12 may be provided separately from the display panel 110 and located beneath the display panel 110, on the side opposite to the viewing surface.

Light may enter through the front surface of the display panel 110, pass through the display panel 110, and reach one or more electronic devices located beneath the display panel 110. For example, the light passing through the display panel 110 may include visible light or infrared light.

One or more electronic devices 11, 12 may receive the light passing through the display panel 110 and perform functions based on the light received. For example, the one or more electronic devices 11, 12 may include one or more imaging devices such as a camera (image sensor), or sensing devices such as a proximity sensor or an illuminance sensor. For example, the sensing device may be an infrared sensor.

Referring to FIG. 1, in one or more aspects, a display area DA may include the first display area DA1, the second display area DA2, and the third display area DA3. At least a portion of the first display area DA1 may overlap with a first electronic device 11, and at least a portion of the third display area DA3 may overlap with a second electronic device 12.

One or more display areas DA1, DA3 including an optical area need to have both a display structure and a light-transmitting structure. That is, since the one or more display areas DA1, DA3 including an optical area are part of the display area DA, light-emitting regions of subpixels for displaying images should be disposed in the one or more display areas DA1, DA3 including an optical area. Additionally, the one or more display areas DA1, DA3 including an optical area should have a light-transmitting structure to allow light to pass through to one or more electronic devices 11, 12.

Although one or more electronic devices 11, 12 need to receive light, they may be positioned beneath the display panel 110 and receive light that passes through the display panel 110. One or more electronic devices 11, 12 may not be exposed on the front surface of the display panel 110. Therefore, when a user views the front surface of the display device 100, the electronic components may not be visible to the user.

For example, the first electronic device 11 may be a sensing device, such as a proximity sensor or an illuminance sensor, and the second electronic device 12 may be a camera. The sensing device may be an infrared sensor. Alternatively, the first electronic device 11 may be a camera, and the second electronic device 12 may be a sensing device.

Hereinafter, for convenience of description, the first electronic device is exemplified as an infrared sensor, and the second electronic device is exemplified as a camera. The camera may be, for example, a camera lens or an image sensor.

The one or more display areas DA1, DA3 including an optical area are capable of displaying images. Therefore, the one or more display areas DA1, DA3 including an optical area may need to include a light-transmitting structure whereas the normal area NA does not require a light-transmitting structure.

Accordingly, the one or more display areas DA1, DA3 including an optical area need to have a transmittance above a certain threshold, and the normal area NA may either be non-transmissive or have a transmittance below the threshold.

For example, the one or more display areas DA1, DA3 including an optical area may differ in resolution, subpixel layout structure, the number of subpixels per unit area, electrode structure, line structure, electrode layout structure, or line layout structure.

The first display area DA1 and the third display area DA3 may have various shapes such as circular, oval, rectangular, hexagonal, or octagonal. Each display area may have the same shape or different shapes.

In the display device 100 according to embodiments of the present disclosure, if the first electronic device 11, which is hidden beneath the display panel 110 and not exposed externally, is an infrared sensor, the display device 100 may be regarded as a display employing UDIR (Under Display Infrared) technology.

In the display device 100 according to embodiments of the present disclosure, if the second electronic device 12, which is hidden beneath the display panel 110 and not exposed externally, is a camera, the display device 100 may be regarded as a display employing UDC (Under Display Camera) technology.

Accordingly, in the display device 100 according to embodiments of the present disclosure, it may not be necessary to form a hole in the display panel 110 for exposing a sensor or a camera, so a reduction in the area of display area DA may not occur. As a result, the size of the bezel may be reduced, and the degree of freedom in design may be increased.

In the display device 100 according to embodiments of the present disclosure, although one or more electronic devices 11, 12 are hidden behind the display panel 110, one or more electronic devices 11, 12 need to be able to properly receive light and perform their designated functions.

Additionally, in the display device 100 according to embodiments of the present disclosure, although one or more electronic devices 11, 12 are hidden behind the display panel 110 and overlap the display area DA, it is preferable that normal image display be possible in the one or more display areas DA1, DA3 including an optical area that overlaps the one or more electronic devices 11, 12.

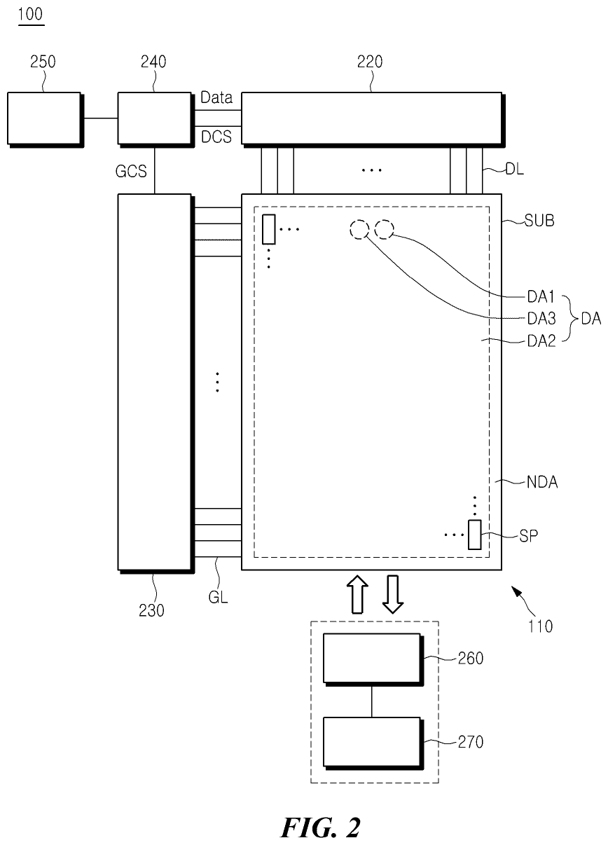

FIG. 2 illustrates a system configuration of an example display device 100 according to embodiments of the present disclosure.

Referring to FIG. 2, in one or more example embodiments, the display device 100 may include the display panel 110 and a display driving circuit as components for displaying images.

The display driving circuit may be a circuit for driving the display panel 110, and include a data driving circuit 220, a gate driving circuit 230, a display controller 240, and other circuit components.

The display panel 110 may include a display area DA in which images can be displayed and a non-display area NDA in which an image is not displayed. The non-display area NDA may be an area outside of the display area DA, and may also be referred to as a non-active area, an edge area, or a bezel area.

The display panel 110 may include a substrate SUB and a plurality of subpixels SP disposed on the substrate SUB. In one or more aspects, the display panel 110 may further include several types of signal lines to drive the plurality of subpixels SP.

In one or more aspects, the display device 100 according to the present disclosure may be a liquid crystal display device, or the like, or a self-emission display device in which light is emitted from the display panel 110 itself. In an example where the display device 100 is a self-emission display device, each of the plurality of subpixels SP may include a light emitting device. For example, the display device 100 may be an organic light emitting display device in which the light emitting device is implemented using an organic light emitting diode (OLED). In another example, the display device 100 may be an inorganic light-emitting display device in which the light emitting device is implemented using an inorganic light emitting diode. In yet another example, the display device 100 may be a quantum dot display device in which the light emitting device is implemented using a quantum dot, which is a semiconductor crystal that emits light by itself.

The structure of each of the plurality of subpixels may vary according to types of display devices. In an example where the display device 100 is a self-emission display device including self-emission subpixels, each subpixel may include a self-emission light emitting device, one or more transistors, and one or more capacitors.

In one or more aspects, several types of signal lines disposed in the display device 100 may include, for example, a plurality of data lines DL for carrying data signals (which may be referred to as data voltages or image signals), a plurality of gate lines GL for carrying gate signals (which may be referred to as scan signals), and the like.

The plurality of data lines DL and the plurality of gate lines GL may intersect one another. Each of the plurality of data lines DL may extend in a first direction. Each of the plurality of gate lines GL may extend in a second direction different from the first direction. For example, the first direction may be the column or vertical direction, and the second direction may be the row or horizontal direction. In another example, the first direction may be the row or horizontal direction, and the second direction may be the column or vertical direction.

The data driving circuit 220 may be a circuit for driving the plurality of data lines DL, and can supply data signals to the plurality of data lines DL. The gate driving circuit 230 may be a circuit for driving the plurality of gate lines GL, and can supply gate signals to the plurality of gate lines GL.

The display controller 240 may be a device for controlling the data driving circuit 220 and the gate driving circuit 230, and can control driving times for the plurality of data lines DL and driving times for the plurality of gate lines GL.

The display controller 240 can supply a data driving control signal DCS to the data driving circuit 220 to control the data driving circuit 220, and supply a gate driving control signal GCS to the gate driving circuit 230 to control the gate driving circuit 230.

The display controller 240 can receive input image data from a host system 250 and supply image data Data based on the input image data to the data driving circuit 220.

The data driving circuit 220 can receive digital image data Data from the display controller 240, convert the received image data Data into analog data signals, and output the resulting analog data signals to the plurality of data lines DL.

The gate driving circuit 230 can receive a first gate voltage corresponding to a turn-on level voltage and a second gate voltage corresponding to a turn-off level voltage along with various gate driving control signals GCS, generate gate signals, and supply the generated gate signals to the plurality of gate lines GL.

In one or more aspects, the data driving circuit 220 may be connected to the display panel 110 by a tape-automated-bonding (TAB) technique, or connected to a conductive pad such as a bonding pad of the display panel 110 by a chip-on-glass (COG) technique or a chip-on-panel (COP) technique, or connected to the display panel 110 by a chip-on-film (COF) technique.

In one or more embodiments, the gate driving circuit 230 may be connected to the display panel 110 by the tape-automated-bonding (TAB) technique, or connected to a conductive pad such as a bonding pad of the display panel 110 by the chip-on-glass (COG) technique or the chip-on-panel (COP) technique, or connected to the display panel 110 by the chip-on-film (COF) technique. In one or more embodiments, the gate driving circuit 230 may be disposed in the non-display area NDA of the display panel 110 by a gate-in-panel (GIP) technique. The gate driving circuit 230 may be disposed on the substrate, or connected to the substrate. In an example where the gate driving circuit 230 is implemented by the GIP technique, the gate driving circuit 230 may be disposed in the non-display area NDA of the substrate. The gate driving circuit 230 may be connected to the substrate in the case of the chip-on-glass (COG) type, the chip-on-film (COF) type, or the like.

In one or more embodiments, at least one of the data driving circuit 220 and the gate driving circuit 230 may be disposed in the display area DA of the display panel 110. For example, at least one of the data driving circuit 220 and the gate driving circuit 230 may be disposed not to overlap with subpixels SP, or disposed to be overlapped with one or more, or all, of the subpixels SP.

The data driving circuit 220 may be located in, and/or electrically connected to, but not limited to, only one side or edge (e.g., an upper portion or a lower portion) of the display panel 110. In one or more aspects, the data driving circuit 220 may be located in, and/or electrically connected to, but not limited to, two sides or edges (e.g., an upper portion and a lower portion) of the display panel 110 or at least two of four sides or edges (e.g., the upper portion, the lower portion, a left portion, and a right portion) of the display panel 110 according to driving schemes, panel design schemes, or the like.

The gate driving circuit 230 may be located in, and/or electrically connected to, but not limited to, only one side or edge (e.g., a left portion or a right portion) of the display panel 110. In one or more aspects, the gate driving circuit 230 may be located in, and/or electrically connected to, but not limited to, two sides or edges (e.g., a left portion and a right portion) of the display panel 110 or at least two of four sides or edges (e.g., an upper portion, a lower portion, the left portion, and the right portion) of the display panel 110 according to driving schemes, panel design schemes, or the like.

The display controller 240 may be implemented in a separate component from the data driving circuit 220, or incorporated in the data driving circuit 220 and thus implemented in an integrated circuit.

In one or more embodiments, to further provide a touch sensing function, as well as an image display function, the display device 100 may include at least one touch sensor, and a touch sensing circuit configured to detect whether a touch event occurs, which is caused by a touch object such as a finger, a pen, or the like, or to detect a corresponding touch position, by sensing the touch sensor.

The touch sensing circuit may include a touch driving circuit 260 capable of generating and providing touch sensing data by driving and sensing the touch sensor, a touch controller 270 capable of detecting the occurrence of a touch event or detecting a touch location (or touch coordinates) using the touch sensing data, and the like.

The touch sensor may include a plurality of touch electrodes. The touch sensor may further include a plurality of touch lines for electrically connecting the plurality of touch electrodes to the touch driving circuit 260.

The touch sensor may be implemented in the form of a touch panel outside the display panel 110 or may be integrated inside the display panel 110.

In the example where the touch sensor is integrated to the inside of the display panel 110, the touch sensor may be formed over the substrate SUB together with signal lines and electrodes related to display driving during the process of manufacturing the display panel 110.

The touch driving circuit 260 can supply a touch driving signal to at least one of a plurality of touch electrodes, and sense at least one of the plurality of touch electrodes to generate touch sensing data.

The touch sensing circuit can perform touch sensing by a self-capacitance sensing technique or a mutual-capacitance sensing technique.

In one or more aspects, the touch driving circuit 260 and the touch controller 270 which are included in the touch sensing circuit, may be implemented in separate devices or may be integrated into a single device. In one or more aspects, the touch driving circuit 260 and the data driving circuit 220 may also be implemented in separate devices, or may be integrated into a single device.

In one or more aspects, the display area DA of the display panel 110 may include a first display area DA1, a second display area DA2, and a third display area DA3. The first display area DA1 and the third display area DA3 may include an optical area OA, and the second display area DA2 may include a normal area NA. The first display area DA1, the second display area DA2, and the third display area DA3 are all capable of displaying images. However, the second display area DA2 does not require a light-transmitting structure or a transmissive area, whereas the first display area DA1 and the third display area DA3 preferably include a light-transmitting structure or a transmissive area.

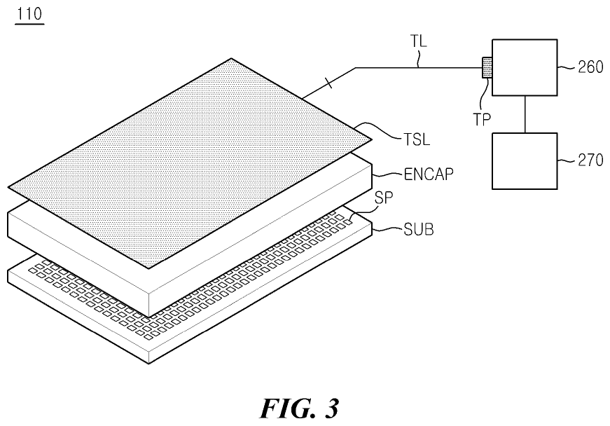

FIG. 3 illustrates an example configuration of display panel 110 according to embodiments of the present disclosure.

Referring to FIG. 3, in one or more example embodiments, a plurality of subpixels SP may be disposed in the display area of the display panel 110. The plurality of subpixels SP may be disposed in a normal area and included in the display area DA of the display panel 110.

Referring to FIG. 3, in one or more example embodiments, to detect a touch application by a user, the display device may include a touch sensor layer TSL including a plurality of sensor electrodes, a touch driving circuit 260 configured to sense the plurality of sensor electrodes, and a touch controller 270 configured to determine whether a touch is applied or a location of the touch (e.g., touch coordinates) based on the sensing result (e.g., touch sensing data) of the touch driving circuit 260.

The touch sensor layer TSL may be integrated into the display panel 110. For example, the touch sensor layer TSL may be disposed on the encapsulation layer ENCAP in the display panel 110.

The display panel 110 may further include a plurality of touch pads TP to which the touch driving circuit 260 is electrically connected, and a plurality of touch routing lines TL for electrically connecting the plurality of sensor electrodes included in the touch sensor layer TSL to the plurality of touch pads TP to which the touch driving circuit 260 is electrically connected.

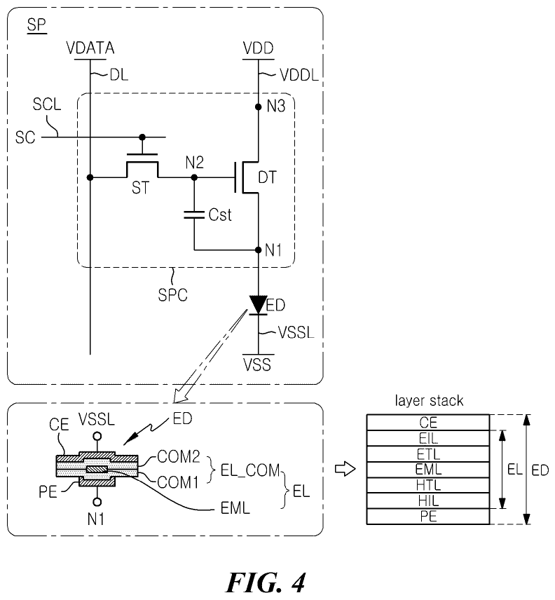

FIG. 4 illustrates an example equivalent circuit of at least one subpixel included in the display device 100 according to embodiments of the present disclosure.

Referring to FIG. 4, in one or more example embodiments, a subpixel circuit SPC included in each subpixel may include a driving transistor DT for driving a light emitting device ED, a scan transistor ST for transferring a data voltage VDATA to the driving transistor DT, a storage capacitor Cst for maintaining a voltage at a certain level during one frame or one or more periods of one frame, and the like.

The driving transistor DT may include a first node N1, a second node N2, and a third node N3.

The first node N1 may be a node electrically connected to the light emitting device ED. The second node N2 may be a node electrically connected to a scan transistor ST. The third node N3 may be a node electrically connected to a driving voltage line VDDL.

The first node N1 may be electrically connected to a pixel electrode PE of the light emitting device ED. A data voltage VDATA may be applied to the second node N2. A driving voltage VDD may be applied to the third node N3.

For example, the second node N2 may be a gate node of the driving transistor DT, the first node N1 may be a source node or a drain node of the driving transistor DT, and the third node N3 may be the drain node or the source node of the driving transistor DT. Hereinafter, for merely convenience of explanation, discussions may be provided based on examples where the first node N1, the second node N2, and the third node N3 are source, gate, and drain nodes of the driving transistor DT, respectively. However, embodiments of the present disclosure are not limited thereto.

The light emitting device ED may include a pixel electrode PE, an intermediate layer EL, and a common electrode CE.

The pixel electrode PE may be an electrode in each subpixel. For example, the pixel electrode PE may be electrically connected directly or indirectly (via another transistor) to the first node N1 of the corresponding driving transistor DT in each subpixel.

The common electrode CE may be an electrode arranged in common to all, or one or more, of a plurality of subpixels SP. For example, a base voltage VSS, which is a type of common driving voltage, may be applied to the common electrode CE through a base voltage line VSSL.

For example, the pixel electrode PE may be an anode electrode, and the common electrode CE may be a cathode electrode. In another example, the pixel electrode PE may be a cathode electrode and the common electrode CE may be an anode electrode. Hereinafter, for convenience of explanation, discussions are provided based on examples where the pixel electrode PE is an anode electrode and the common electrode CE is a cathode electrode.

The intermediate layer EL may include an emission layer EML and a common intermediate layer EL_COM.

The emission layer EML may be disposed in a light emitting area of each of the plurality of subpixels SP. For example, the emission layer EML may be disposed only in each of the plurality of subpixels SP. In another example, the emission layer EML may be disposed in common in all, or two or more, of a plurality of subpixels SP. In another example, the emission layer EML may be disposed only in a light emitting area. In another example, the emission layer EML may be disposed in both a light emitting area and a non-light emitting area.

The common intermediate layer EL_COM may be disposed in common across all, or two or more, of a plurality of subpixels SP. The common intermediate layer EL_COM may be disposed in common in a plurality of light emitting areas EA and one or more non-light emitting areas.

The common intermediate layer EL_COM may include a first common intermediate layer COM1 and a second common intermediate layer COM2. The first common intermediate layer COM1 may be disposed between the pixel electrode PE and the emission layer EML and may include at least one layer (e.g., an organic layer). The second common intermediate layer COM2 may be disposed between the emission layer EML and the common electrode CE and may include at least one layer (e.g., an organic layer). For example, the first common intermediate layer COM1 may include a hole injection layer HIL, a hole transport layer HTL, and the like. The second common intermediate layer COM2 may include an electron transport layer ETL, an electron injection layer EIL, and the like.

The hole injection layer HIL can inject holes from the pixel electrode PE to the hole transport layer HTL. The hole transport layer HTL can transport holes to the emission layer EML. The electron injection layer EIL can inject electrons from the common electrode CE to the electron transport layer ETL. The electron transport layer ETL can transport electrons to the emission layer EML. To emit light, each light emitting device ED may include a portion in which the corresponding pixel electrode PE, the emission layer EML in the corresponding intermediate layer EL, and the corresponding common electrode CE overlap with each other. Each light emitting device ED may provide a corresponding light emitting area EA. For example, each light emitting area EA may be defined as an area where the corresponding pixel electrode PE, the emission layer EML of the corresponding intermediate layer EL, and the corresponding common electrode CE overlap with each other.

In one or more aspects, the light emitting device ED may be an organic light emitting diode (OLED), an inorganic light emitting diode, a quantum dot light emitting device, a micro light emitting diode, a mini light emitting diode, and the like.

The scan transistor ST may be turned on or off by a scan signal SC, which is one type of gate signal carried through a scan signal line SCL, which is one type of gate line GL, and may be electrically connected between the second node N2 of the driving transistor DT and a data line DL.

The storage capacitor Cst may be electrically connected between the first node N1 and the second node N2 of the driving transistor DT.

The subpixel circuit SPC may have a 2T(Transistor)1C(Capacitor) structure including two transistors (DT and ST) and one capacitor (Cst) as illustrated in FIG. 4. In one or more aspects, the subpixel circuit SPC may further include one or more transistors or one or more capacitors in the 2T1C structure.

In one or more embodiments, the storage capacitor Cst, which may be present between the first node N1 and the second node N2 of the driving transistor DT, may be an external capacitor intentionally configured or designed to be located outside of the driving transistor DT, other than internal capacitors, such as parasitic capacitors (e.g., a gate-to-source capacitance Cgs, a gate-to-drain capacitance Cgd, and the like). Each of the driving transistor DT and the scan transistor ST may be an n-type transistor or a p-type transistor.

Since circuit elements (e.g., a light emitting device ED such as an organic light emitting diode (OLED)) including an organic material in each subpixel may be easily damaged by external moisture or oxygen, an encapsulation layer may be disposed in the display panel to prevent the external moisture or oxygen from penetrating the circuit elements (e.g., the light emitting device ED). The encapsulation layer may be disposed such that it covers one or more light emitting devices ED.

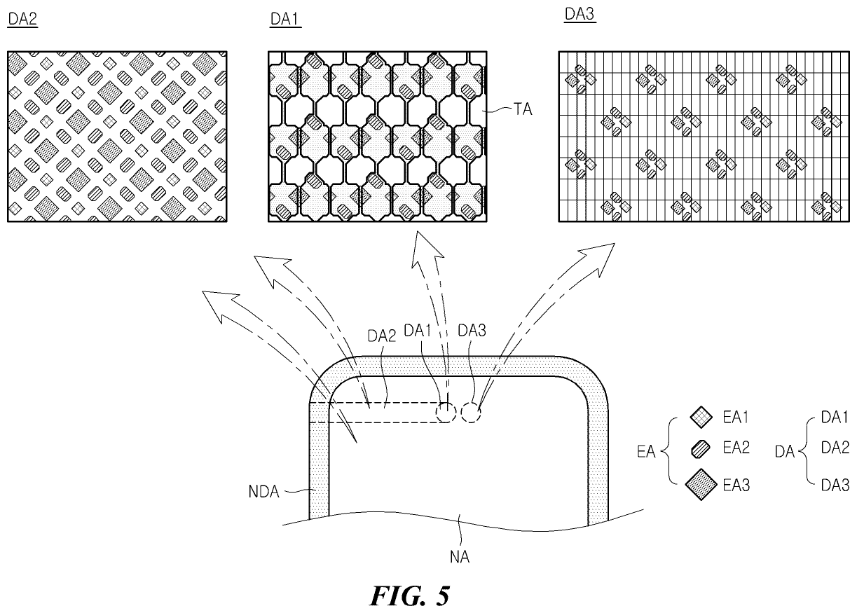

FIG. 5 illustrates a first display area DA1, a second display area DA2 and a third display area DA3 included in a display panel according to embodiments of the present disclosure.

Referring to FIG. 5, in one or more embodiments, the display panel 110 may include the display area DA in which images can be displayed and the non-display area which images are not displayed.

Referring to FIG. 5, the display area DA may include the first display area DA1, the third display area DA3, and the second display area located outside the first display area DA1 and the third display area DA3. The first display area DA1 and the third display area DA3 may include a transmissive area TA and a non-transmissive area NTA which may be disposed outside the transmissive area TA.

The non-transmissive area NTA may include a plurality of light emitting areas EA. The non-transmissive area NTA may include a plurality of light emitting devices forming the light emitting area EA, and a plurality of subpixel circuits which may drive the plurality of light emitting devices. The plurality of the light emitting devices may partially overlap with the plurality of subpixel circuits.

In other words, the first display area DA1 and the third display area DA3 may include the transmissive area TA and the plurality of light emitting areas EA, and may also be regions in which the plurality of subpixel circuits can be disposed.

For example, the non-transmissive areas NTA within the first display area DA1 and the third display area DA3 may be regions through which light does not pass. The second display area DA2 may also be a region through which light does not pass.

In another example, in the first display area DA1 and the third display area DA3, the light transmittance of the non-transmissive area NTA may be lower than that of the transmissive area TA.

The display area DA may include the plurality of light emitting areas EA. Since the first display area DA1, the second display area DA2, and the third display area DA3 are included in the display area DA, each of the first display area DA1, the second display area DA2, and the third display area DA3 may also include the plurality of the light emitting areas EA.

The plurality of light emitting areas EA disposed in the display area DA may include a first color light emitting area EA1 that emits light of a first color, a second color light emitting area EA2 that emits light of a second color, and a third color light emitting area EA3 that emits light of a third color. The first color light emitting area EA1, the second color light emitting area EA2, and the third color light emitting area EA3 may have an area different from the others. The first color, the second color, and the third color may be different from each other and may include various colors. For example, the first color, the second color, and the third color may include red, green, and blue.

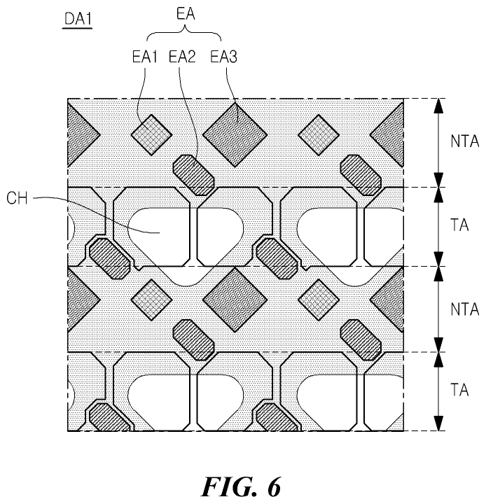

FIG. 6 illustrates an enlarged view of the first display area DA1 in a display panel according to embodiments of the present disclosure.

Referring to FIG. 6, the first display area DA1 may include a plurality of light emitting areas EA and a transmissive area TA. In the first display area DA1, a region outside the transmissive area TA may include the plurality of light emitting areas EA.

In the first display area DA1, a non-transmissive area NTA may include the plurality of light emitting areas EA.

The transmissive area TA in the first display area DA1 may include a common electrode hole CH. Hereinafter, each of the common electrode hole CH may also be referred to as a transmissive area TA.

A common electrode hole CH may exist between two adjacent light emitting areas.

The common electrode hole CH may have various shapes, such as a circular shape, an oval shape, a rectangular shape, a hexagonal shape, or an octagonal shape.

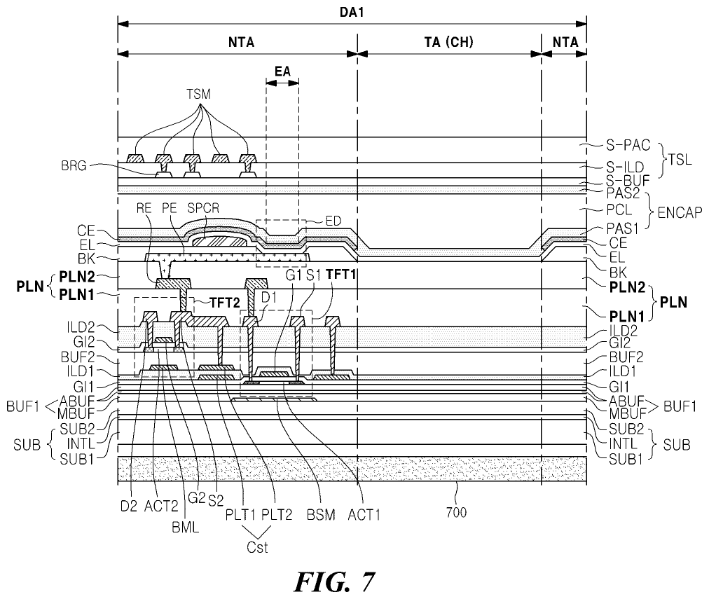

FIG. 7 is an example cross-sectional view of a first display area DA1 in a display panel according to embodiments of the present disclosure.

The display panel may include a transistor forming part, a light emitting device forming part, an encapsulation part, and a touch sensor.

The transistor forming part may include a substrate SUB, a first buffer layer BUF1 on the substrate SUB, a plurality of transistors TFT1 and TFT2 formed on the first buffer layer BUF1, a storage capacitor Cst, and various electrodes or signal lines.

The substrate SUB may include a first substrate SUB1 and a second substrate SUB2, and may include a substrate intermediate layer INTL between the first substrate SUB1 and the second substrate SUB2. Here, for example, the substrate intermediate layer INTL may be an inorganic layer and may block moisture penetration.

A lower shield metal BSM may be disposed on the substrate SUB. The lower shield metal BSM may be located below a first active layer ACT1 of a first transistor TFT1.

The first buffer layer BUF1 may be a single layer or a multi-layer. If the first buffer layer BUF1 is a multi-layer, the first buffer layer BUF1 may include a multi-buffer layer MBUF and an active buffer layer ABUF.

Various transistors TFT1 and TFT2, a storage capacitor Cst, and various electrodes or signal lines may be formed on the first buffer layer BUF1.

For example, the transistors TFT1 and TFT2 formed on the first buffer layer BUF1 may be made of the same material and located in the same layers. Alternatively, as shown in FIG. 6, a first transistor TFT1 and a second transistor TFT2 among the transistors TFT1 and TFT2 may be made of different materials, and may be located in different layers.

The first transistor TFT1 may include a first active layer ACT1, a first gate electrode G1, a first source electrode S1, and a first drain electrode D1. The second transistor TFT2 may include a second active layer ACT2, a second gate electrode G2, a second source electrode S2, and a second drain electrode D2.

The second active layer ACT2 of the second transistor TFT2 may be located higher than the first active layer ACT1 of the first transistor TFT1.

The first active layer ACT1 of the first transistor TFT1 and the second active layer ACT2 of the second transistor TFT2 may include different semiconductor materials. For example, the first active layer ACT1 of the first transistor TFT1 may include a semiconductor material different from the second active layer ACT2 of the second transistor TFT2. For example, the first active layer ACT1 of the first transistor TFT1 may include a silicon-based semiconductor material. For example, the silicon-based semiconductor material may include low-temperature polycrystalline silicon (LTPS). For example, the second active layer ACT2 of the second transistor TFT2 may include an oxide semiconductor material. For example, oxide semiconductor materials may include indium gallium zinc oxide (IGZO), indium gallium zinc tin oxide (IGZTO), zinc oxide (ZnO), cadmium oxide (CdO), indium oxide (InO), zinc tin oxide (ZTO) or zinc indium tin oxide (ZITO).

The first buffer layer BUF1 may be disposed below the first active layer ACT1 of the first transistor TFT1, and a second buffer layer BUF2 may be disposed below the second active layer ACT2 of the second transistor TFT2.

That is, the first active layer ACT1 of the first transistor TFT1 may be located on the first buffer layer BUF1, and the second active layer ACT2 of the second transistor TFT2 may be located on the second buffer layer BUF2. Here, the second buffer layer BUF2 may be located higher than the first buffer layer BUF1.

The first active layer ACT1 of the first transistor TFT1 may be disposed on the first buffer layer BUF1, and a first gate insulating layer may be disposed on the first active layer ACT1 of the first transistor TFT1. A first gate electrode G1 of the first transistor TFT1 may be disposed on the first gate insulating layer GI1, and a first interlayer insulating layer ILD1 may be disposed on the first gate electrode G1 of the first transistor TFT1.

The first active layer ACT1 of the first transistor TFT1 may include a first channel area overlapping the first gate electrode G1, a first source connection area located on one side of the first channel area, and a first drain connection area located on the other side of the first channel area.

The second buffer layer BUF2 may be disposed on the first interlayer insulating layer ILD1.

The second active layer ACT2 of the second transistor TFT2 may be disposed on the second buffer layer BUF2, and a second gate insulating layer GI2 may be disposed on the second active layer ACT2. A second gate electrode G2 of the second transistor TFT2 may be disposed on the second gate insulating layer GI2, and a second interlayer insulating layer ILD2 may be disposed on the second gate electrode G2.

The second active layer ACT2 of the second transistor TFT2 may include a second channel area overlapping the second gate electrode G2, a second source connection area located on one side of the second channel area, and a second drain connection area located on the other side of the second channel area.

A first source electrode S1 and a first drain electrode D1 of the first transistor TFT1 may be disposed on the second interlayer insulating layer ILD2. Additionally, a second source electrode S2 and a second drain electrode D2 of the second transistor TFT2 may be disposed on the second interlayer insulating layer ILD2.

The first source electrode S1 and the first drain electrode D1 of the first transistor TFT1 may be connected to the first source connection area and the first drain connection area of the first active layer ACT1, respectively, via the through holes of the second interlayer insulating layer ILD2, the second gate insulating layer GI2, the second buffer layer BUF2, the first interlayer insulating layer ILD1 and the first gate insulating layer GI1.

The second source electrode S2 and the second drain electrode D2 of the second transistor TFT2 may be connected to the second source connection area and the second drain connection area of the second active layer ACT2, respectively through the through holes in the second interlayer insulating layer ILD2 and the second gate insulating layer GI2.

The storage capacitor Cst may include a first capacitor electrode PLT1 and a second capacitor electrode PLT2.

The first capacitor electrode PLT1 may be electrically connected to the second gate electrode G2 of the second transistor TFT2, and the second capacitor electrode PLT2 may be electrically connected to the second source electrode S2 of the second transistor TFT2.

A lower metal BML may be disposed under the second active layer ACT2 of the second transistor TFT2. The lower metal BML may overlap with all or part of the second active layer ACT2.

For example, the lower metal BML may be electrically connected to the second gate electrode G2. As another example, the lower metal BML may serve as a light shield for blocking light coming from the lower part. In this case, the lower metal BML may be electrically connected to the second source electrode S2.

For example, the first transistor TFT1 may be a driving transistor for driving the light emitting device ED, and the second transistor TFT2 may be a scan transistor.

The display panel may include a planarization layer PLN disposed on the first transistor TFT1 and the second transistor TFT2.

For example, the planarization layer PLN may include a first planarization layer PLN1. The first planarization layer PLN1 may be formed on the first source electrode S1 and the first drain electrode D1 of the first transistor TFT1 and the second source electrode S2 and the second drain electrode D2 of the second transistor TFT2.

A connection electrode RE may be disposed on the first planarization layer PLN1. The connection electrode RE may be an electrode for relaying the electrical connection between the second source electrode S2 of the second transistor TFT2 and the pixel electrode PE of the light emitting device ED. The connection electrode RE may be electrically connected to the second source electrode S2 of the second transistor TFT2 through a hole in the first planarization layer PLN1.

The planarization layer PLN disposed on the display panel may further include a second planarization layer PLN2 on the first planarization layer PLN1. For example, the second planarization layer PLN2 may be disposed while covering the connection electrode RE located on the first planarization layer PLN1.

Referring to FIG. 7, the light emitting device forming part may be located on the second planarization layer PLN2, and may further include a pixel electrode PE, intermediate layer EL, and common electrode CE for forming the light emitting device ED.

The light emitting device ED may be configured in an area where the pixel electrode PE, the intermediate layer EL, and the common electrode CE overlap.

The pixel electrode PE may be disposed on the second planarization layer PLN2. The pixel electrode PE may be connected to the connection electrode RE through a hole in the second planarization layer PLN2.

A bank BK may be disposed on the pixel electrode PE.

The bank BK may include a bank hole, and a portion of the pixel electrode PE may be exposed through the bank hole. That is, the bank hole formed in the bank BK may overlap a portion of the pixel electrode PE.

The intermediate layer EL may be disposed on the bank BK. The intermediate layer EL may contact a portion of the pixel electrode PE through the bank hole.

At least one spacer SPCR may be additionally disposed between the intermediate layer EL and the bank BK.

A common electrode CE may be disposed on the intermediate layer EL. The common electrode CE may include a common electrode hole CH. The common electrode hole CH formed in the common electrode CE may be disposed in the first display area DA1. One common electrode hole CH may exist between two adjacent emission areas.

Referring to FIG. 7, an encapsulation part may be located on the common electrode CE. The encapsulation part may include an encapsulation layer ENCAP formed on the common electrode CE.

The encapsulation layer ENCAP may be a layer which prevents moisture or oxygen from penetrating into the light emitting device ED. In particular, the encapsulation layer ENCAP may prevent moisture or oxygen from penetrating into the intermediate layer EL, which may include an organic layer. Here, the encapsulation layer ENCAP may be composed of a single layer or multiple layers.

The encapsulation layer ENCAP may include a first encapsulation layer PAS1, a second encapsulation layer PCL, and a third encapsulation layer PAS2. For example, the first encapsulation layer PAS1 and the third encapsulation layer PAS2 may be inorganic layers, and the second encapsulation layer PCL may be an organic layer. Since the second encapsulation layer PCL is composed of an organic layer, the second encapsulation layer PCL may function as a planarization layer.

The display panel according to embodiments of the present disclosure may include a touch sensor layer TSL formed on the encapsulation layer ENCAP. The touch sensor layer TSL may include touch sensor metals TSM and bridge metals BRG, and may further include one or more insulating layers such as a sensor buffer layer S-BUF, a sensor interlayer insulating layer S-ILD and a sensor protection layer S-PAC. Here, the sensor interlayer insulating layer S-ILD may be omitted.

The sensor buffer layer S-BUF may be disposed on the encapsulation layer ENCAP. The bridge metals BRG may be disposed on the sensor buffer layer S-BUF, and the sensor interlayer insulating layer S-ILD may be disposed on the bridge metals BRG. Here, the sensor buffer layer S-BUF may be omitted.

The touch sensor metals TSM may be disposed on the sensor interlayer insulating layer S-ILD. Some of the touch sensor metals TSM may be connected to the corresponding bridge metal BRG through holes in the sensor interlayer insulating layer S-ILD.

The touch sensor metals TSM and bridge metals BRG may be disposed in the non-transmissive area NTA in the first display area DA1. The touch sensor metals TSM and bridge metals BRG may not be disposed in the transmissive area TA in the first display area DA1. The touch sensor metals TSM and the bridge metals BRG may be arranged so as not to overlap the light emitting area EA in the non-transmissive area NTA.

A plurality of touch sensor metals TSM may form one touch electrode (or one touch electrode line), and may be arranged in a mesh shape and electrically connected. A portion of the touch sensor metals TSM and another portion of the touch sensor metals TSM may be electrically connected through a bridge metal BRG to form one touch electrode (or one touch electrode line).

The sensor protection layer S-PAC may be disposed while covering the touch sensor metals TSM and the bridge metals BRG.

At least a portion of the touch sensor metal located on the encapsulation layer ENCAP in the display area DA may be extended and disposed along an outer inclined surface of the encapsulation layer ENCAP and electrically connected to a pad located further outside the outer inclined surface of the encapsulation layer ENCAP. Here, the pad may be disposed in the non-display area NDA and may be a metal pattern to which the touch driving circuit is electrically connected.

In the transmissive area TA, the common electrode CE may have a common electrode hole CH formed therein. That is, the common electrode hole CH may overlap the transmissive area TA.

For example, in the transmissive area TA, a hole may be formed in the bank BK. That is, there may be a hole in the bank BK which overlaps the transmissive area TA.

The cross-sectional structure of the second display area DA2 may be same as the cross-sectional structure of the non-transmissive area NTA in the first display area DA1.

The cross-sectional structure of the third display area DA3 may be same as the cross-sectional structure of the first display area DA1.

At least a portion of the first display area DA1 may overlap an electronic device 700. The electronic device 700 may be a first electronic device 11 and/or a second electronic device 12.

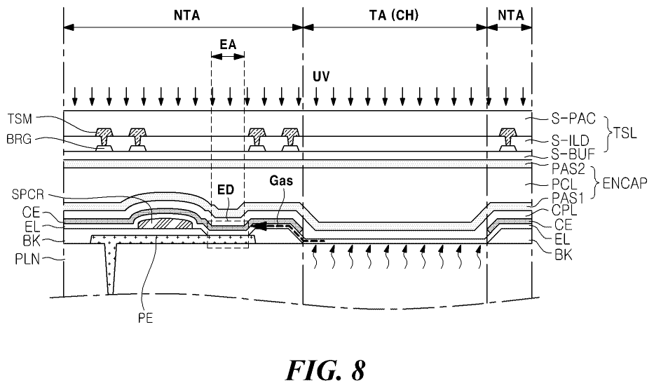

FIG. 8 illustrates an ultraviolet reliability evaluation process of a display panel. In this case, the layered structure in FIG. 8 is the same as that in FIG. 7. Accordingly, descriptions of the identical layers may be omitted.

During the manufacturing of a display panel, an ultraviolet reliability evaluation process may be performed.

A first display area and a third display area may include a transmissive area TA and a non-transmissive area NTA. Furthermore, a second display area may include a non-transmissive area NTA.

The non-transmissive area NTA included in the first display area, the second display area, and the third display area may include a light emitting area EA in which a light emitting device ED is disposed.

In the non-transmissive area NTA, a common electrode CE may be disposed.

However, in the transmissive area TA, the common electrode CE may not be disposed, and a common electrode hole CH may be formed instead.

During the ultraviolet reliability evaluation process, ultraviolet may be irradiated onto the top surface of the display panel. In the non-transmissive area NTA, the ultraviolet light entering display panel may be blocked by a pixel electrode PE, the common electrode CE, a transistor TFT, and a plurality of touch sensor metals TSM, and therefore may not reach the planarization layer PLN. However, in the transmissive area TA, since some of the pixel electrode PE, the common electrode CE, the transistor TFT, and the plurality of touch sensor metals TSM may be absent, the ultraviolet light entering the display panel 110 may reach the planarization layer PLN through the common electrode hole CH.

If the ultraviolet light reaches the planarization layer PLN, gas may be generated from the planarization layer PLN. This phenomenon is referred to as “out-gassing”.

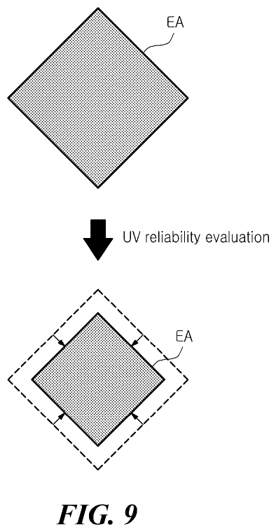

FIG. 9 illustrates a pixel shrinkage resulting from an ultraviolet reliability evaluation process of an example display panel.

After a manufacturing of the display panel was completed, image quality evaluations were conducted and degradation in image quality was frequently observed. The inventors analyzed this phenomenon and, through experimentation, identified its cause, which was found to be related to the ultraviolet light irradiated during an ultraviolet reliability evaluation process. This will be described in detail below.

During the ultraviolet reliability evaluation process, gas generated from a planarization layer in a transmissive area may travel along an intermediate layer to an adjacent light emitting area EA. The gas transferred to the light emitting area EA may infiltrate the edge of a light emitting device, and as a result, as shown in FIG. 9, the area of the light emitting area EA may decrease. This phenomenon is referred to as “pixel shrinkage”.

Due to the pixel shrinkage, the brightness of the light emitting device affected by the pixel shrinkage may decrease, which may lead to a degradation in display quality. Furthermore, pixel shrinkage may also reduce the lifetime of the light emitting device.

The brightness of the light emitting device affected by the pixel shrinkage may differ from that of a light emitting device not affected by the pixel shrinkage. A brightness inconsistency among the light emitting devices may cause image display imbalance, which may lead to degradation in display quality.

Therefore, in one or more embodiments of the present disclosure, the display device may have a structure that prevents pixel shrinkage caused by out-gassing in the transmissive area TA and improves the performance of an infrared sensor.

For example, in one or more embodiments of the present disclosure, the display device may include a black planarization layer and a planarization layer structure differentiated by area to prevent pixel shrinkage caused by out-gassing in the transmissive area TA.

In another example, in one or more embodiments of the present disclosure, the display device may have a structure including a planarization layer with an opening, in order to prevent pixel shrinkage caused by out-gassing in the transmissive area.

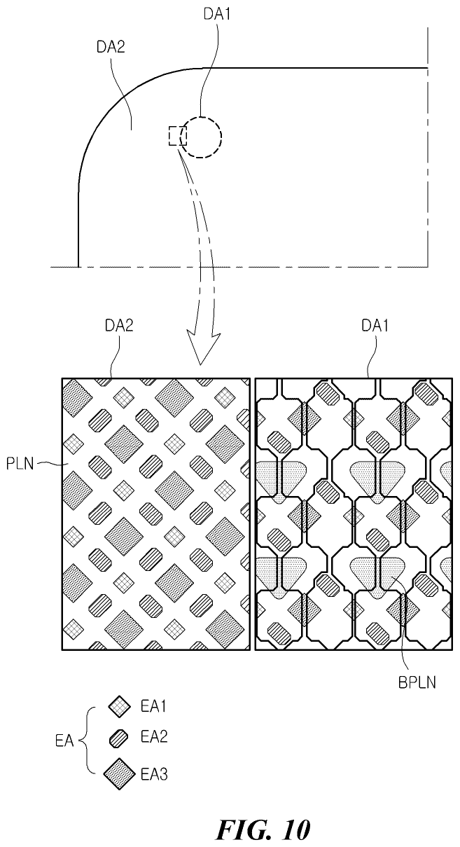

Hereinafter, improvements in infrared sensor performance and a structure for preventing pixel shrinkage in the display panel according to embodiments of the present disclosure will be described in detail with reference to FIGS. 10 to 27. It is noted that FIGS. 1 to 9 are also referenced in the following description.

FIG. 10 is a plan view of a first display area DA1 and a second display area DA2 in a display panel according to embodiments of the present disclosure.

Referring to FIG. 10, in one or more embodiments of the present disclosure, a display device may have a planarization layer structure that is differentiated by area to prevent pixel shrinkage caused by out-gassing in the transmissive area.

A first display area DA1, through which light can pass, may have a different planarization layer structure from a second display area DA2, through which light cannot pass.

For example, in one or more embodiments of the present disclosure, the display device may include a non-black planarization layer disposed in the second display area DA2 and a black planarization layer BPLN disposed in the first display area. Hereinafter, the planarization layer which disposed outside the black planarization layer BPLN may referred to as a non-black planarization layer PLN.

The black planarization layer BPLN disposed in the first display area DA1 may differ from the planarization layer PLN disposed in the second display area DA2 in at least one of material and optical characteristics. For example, the optical characteristics may include wavelength-dependent light transmittance.

For example, the black planarization layer BPLN may be disposed over the entire first display area DA1. In another example, as shown in FIG. 10, the black planarization layer BPLN may be disposed in a portion of the first display area DA1, for example, in the transmissive area.

For example, in one or more embodiments of the present disclosure, the planarization layer PLN included in the display device may be an insulated layer disposed between the substrate and a pixel electrode, and may include a first part disposed in all or a portion of the first display area DA1 and a second part that is different from the first part.

The first part and the second part of the planarization layer may be distinguished from each other in terms of position and material.

The first part of the planarization layer may overlap the transmissive area through which light of a specific wavelength (e.g., infrared) can pass, and the second part of the planarization layer may correspond to an area other than the transmissive area, or to an area different from the first display area DA1 that includes the transmissive area.

The first part of the planarization layer may be the black planarization layer BPLN, and the second part of the planarization layer may be a planarization layer corresponding to a non-black planarization layer PLN.

The first part and the second part of the planarization layer may include different materials. For example, the first part of the planarization layer may include lactam black, and the second part of the planarization layer may include photoacrylic (PAC).

Hereinafter, a structure in which the black planarization layer BPLN is disposed in the transmissive area within the first display area DA1 will be described.

The transmissive area in which the black planarization layer BPLN is disposed may overlap with a first electronic device. Hereinafter, the first electronic device may be referred to as an infrared sensor that performs sensing using infrared light passing through the transmissive area.

Although ultraviolet light may reach the black planarization layer BPLN through a common electrode hole, the black planarization layer BPLN is less reactive to ultraviolet light than the non-black planarization layer. Therefore, out-gassing and pixel shrinkage may occur less in areas where the black planarization layer BPLN is disposed than in areas where the non-black planarization layer is disposed.

As a result, brightness degradation of a light emitting device on the black planarization layer BPLN may be prevented. Furthermore, brightness difference between light emitting devices disposed on the black planarization layer BPLN and those disposed on the non-black planarization layer may be reduced. Accordingly, image quality may be significantly improved.

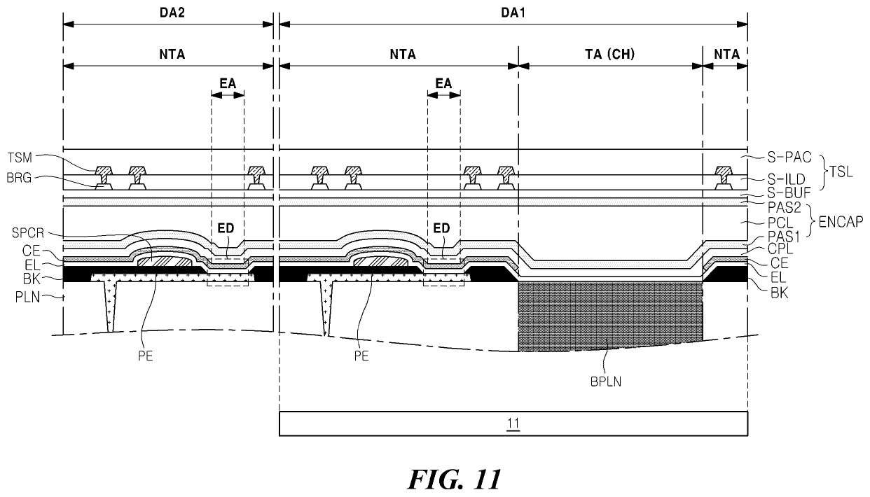

FIG. 11 is a cross-sectional view of a first display area DA1 and a second display area DA2 in a display panel according to embodiments of the present disclosure. The layered structure in FIG. 11 is same as that in FIG. 7. Therefore, descriptions of the identical layers may be omitted.

Referring to FIG. 11, the display panel according to embodiments of the present disclosure may include a transmissive area TA, through which light can pass, and a non-transmissive area NTA, through which light cannot pass or can pass only at a very low transmittance.

Referring to FIG. 11, a common electrode CE may include a plurality of common electrode holes CH overlapping with the transmissive area TA.

The first display area DA1 may include the transmissive area TA including a plurality of common electrode holes CH and the non-transmissive area NTA including a plurality of light emitting areas EA.

The second display area DA2 may be located outside the first display area DA1 and may include the non-transmissive area NTA.

A light emitting device ED may be formed by overlapping a pixel electrode PE, an intermediate layer EL, and a common electrode CE.

The transmissive area TA may be an area through which light can pass and in which the light emitting device ED is not disposed.

If at least one of the pixel electrode PE, the intermediate layer EL, and the common electrode CE is not present, the light emitting device ED is not formed, and accordingly, the light emitting area EA is also not formed. In addition, the pixel electrode PE is not disposed in the transmissive area TA.

Referring to FIG. 11, the first display area DA1 according to embodiments of the present disclosure may include: a pixel electrode PE on a substrate SUB; an emission layer EML included in an intermediate layer EL on the pixel electrode PE; a common electrode CE having a plurality of holes, disposed on the emission layer EML and positioned in the transmissive area TA; a second encapsulation layer PCL disposed on the common electrode CE; and a black planarization layer BPLN disposed between the substrate SUB and the pixel electrode PE.

The black planarization layer BPLN may overlap with a plurality of common electrode holes CH that overlap the transmissive area TA. The non-black planarization layer may be disposed in an area other than the transmissive area TA.

For example, the black planarization layer BPLN may be formed by a photolithography process or an inkjet printing process.

If the black planarization layer BPLN is formed by the inkjet printing process, it may be formed in a shape that minimizes pixel shrinkage caused by ultraviolet irradiation.

The black planarization layer BPLN and the second encapsulation layer PCL may be composed of organic materials. Since the black planarization layer BPLN may enhance panel reliability against ultraviolet light, the ultraviolet reactivity of the black planarization layer BPLN may be lower than that of the second encapsulation layer PCL.

The reactivity of the black planarization layer BPLN to ultraviolet light may be lower than that of non-black planarization layer PLN.

Accordingly, out-gassing and pixel shrinkage in the area where the black planarization layer BPLN is disposed may be less than in the area where the non-black planarization layer PLN is disposed.

A display device according to embodiments of the present disclosure may include a bank BK that is disposed on a pixel electrode PE, and that has a first opening overlapping the transmissive area TA and a second opening overlapping at least a portion of the pixel electrode PE. In this case, the first opening may also overlap the black planarization layer BPLN.

In this case, the bank BK may be a black bank.

If the bank BK is implemented as a black bank, contrast degradation in an organic light emitting display device may be prevented even when external light is bright.

In the first display area DA1, a first electronic device 11, such as an infrared sensor, may be disposed under the substrate SUB.

For example, the black planarization layer BPLN may have an infrared transmittance characteristic. In another example, the black planarization layer BPLN may not only have an infrared transmittance characteristic but also have a visible light filtering characteristic.

If the black planarization layer BPLN has an infrared transmittance characteristic and a visible light filtering characteristic, the difference between infrared and visible light transmittance of black planarization layer BPLN may be greater than that of the second encapsulation layer PCL.

Since the difference between infrared and visible light transmittance of the black planarization layer BPLN is greater than that of a planarization layer made of photoacrylic, the infrared reception rate of a first electronic device 11 overlapping the black planarization layer BPLN may be improved.

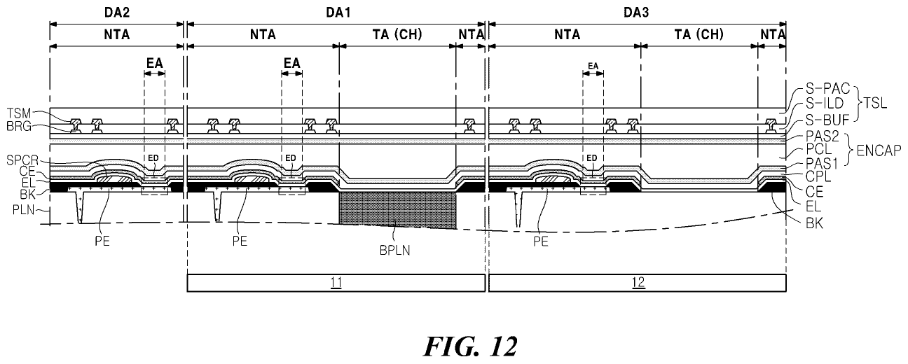

FIG. 12 is an example cross-sectional view of a first display area DA1, a second display area DA2, and a third display area DA3 in a display panel according to embodiments of the present disclosure.

Referring to FIG. 12, the third display area DA3 may be located outside the first display area DA1 and include a transmissive area TA and a non-transmissive area NTA.

A second electronic device 12 may be disposed below the substrate in the third display area DA3. The second electronic device 12 may be different in type from a first electronic device 11 that is disposed below the substrate in the first display area DA1. For example, the first electronic device 11 may be an infrared sensor, and the second electronic device 12 may be a camera.

In consideration of this, the black planarization layer BPLN may be disposed in the first display area DA1, but may not be disposed in the third display area DA3.

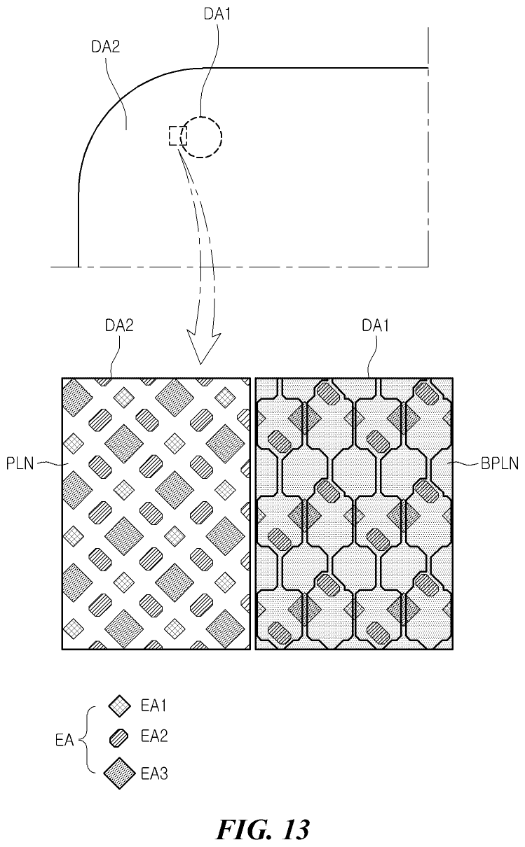

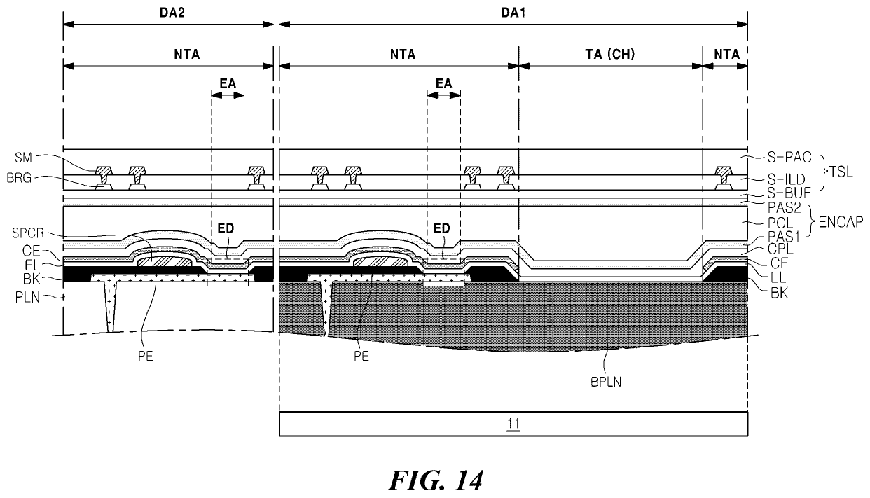

FIGS. 13 and 14 are example plan and cross-sectional views of a first display area DA1 and a second display area DA2 in a display panel 110 according to embodiments of the present disclosure.

Referring to FIGS. 13 and 14, the black planarization layer BPLN may be disposed in all area of the first display area DA1.

Referring to FIGS. 13 and 14, the black planarization layer BPLN may be disposed in the first display area DA1, and a non-black planarization layer PLN may be dispose d in the second display area DA2.

In the first display area DA1, a first electronic device, such as an infrared sensor, may be disposed below a substrate.

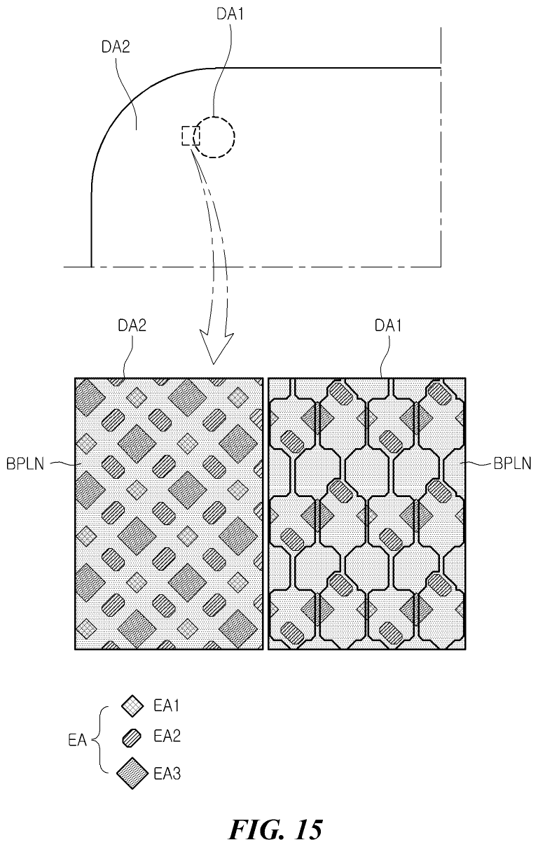

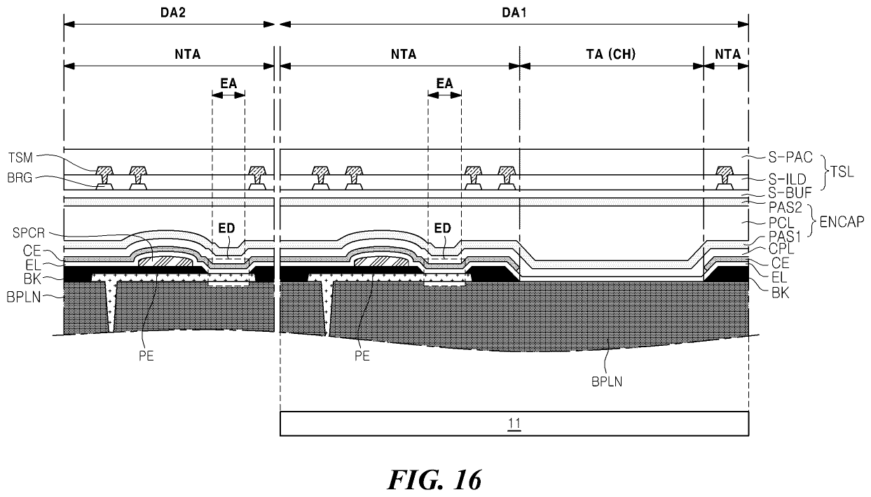

FIGS. 15 and 16 are example plan view and cross-sectional views of a first display area DA1 and a second display area DA2 in a display panel according to embodiments of the present disclosure.

Referring to FIGS. 15 and 16, the black planarization layer BPLN may be disposed over the entire area of the first display area DA1 and the second display area DA2.

In the first display area DA1, a first electronic device, such as an infrared sensor, may be disposed below a substrate.

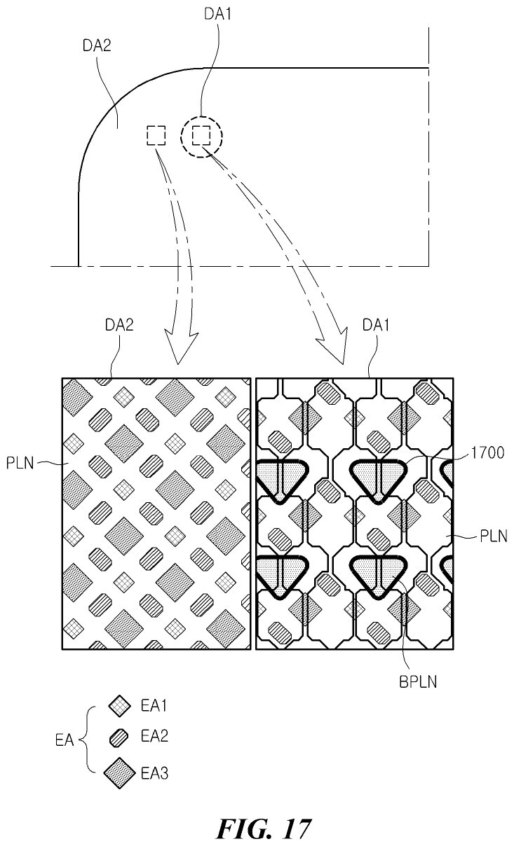

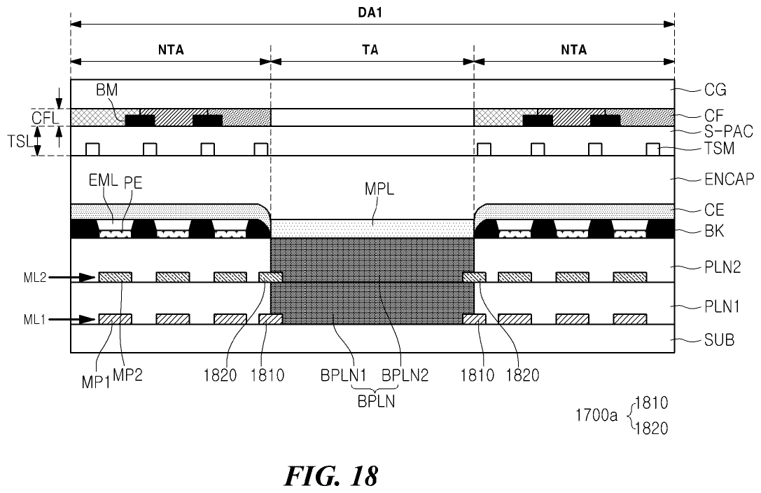

FIG. 17 is an example plan view of a first display area DA1 and a second display area DA2 in a display panel according to embodiments of the present disclosure. FIGS. 18 to 21 are example simplified cross-sectional views illustrating a structure in which a metal wall is disposed at a boundary between a black planarization layer BPLN and a non-black planarization layer PLN in the first display area DA1.

Referring to FIGS. 17 to 21, a metal wall 1700 may be disposed in the transmissive area TA in the first display area DA1. A common electrode hole CH may also be referred to as a transmissive area TA.

Referring to FIGS. 17 to 21, the metal wall 1700 may be disposed along the boundary of the transmissive area TA.

Referring to FIGS. 17 to 21, the metal wall 1700 may be disposed at the boundary between the black planarization layer BPLN and the non-black planarization layer PLN.

Referring to FIGS. 18 to 21, the metal wall 1700, which is disposed at a boundary between the black planarization layer BPLN and the non-black planarization layer PLN in the first display area DA1, may be formed in various shapes or be composed of various metal layers.

Referring to FIG. 18, the planarization layer PLN may include a first planarization layer PLN1 and a second planarization layer PLN2 on the first planarization layer PLN1. The black planarization layer BPLN may include a first black planarization layer BPLN1 and a second black planarization layer BPLN2 on the first black planarization layer BPLN1. The first planarization layer PLN1, the second planarization layer PLN2, the first black planarization layer BPLN1, and the second black planarization layer BPLN2 may be disposed on a substrate SUB.

The black planarization layer BPLN may be formed by a photolithography process or an inkjet printing process. If the black planarization layer BPLN is formed by the inkjet printing process, the presence of the metal wall 1700 may enable the ink to be precisely deposited only in a desired region due to surface tension or the like. Accordingly, the black planarization layer BPLN can be accurately formed in the desired region.

The black planarization layer BPLN can be disposed overlapping a common electrode hole CH that overlaps the transmissive area TA. The non-black planarization layer PLN may be disposed in other areas.

A display panel may include a first metal layer ML1 and a second metal layer ML2 to form various electrodes or lines. For example, the first metal layer ML1 may be a metal layer below the first planarization layer PLN1, and the second metal layer ML2 may be a metal layer disposed between the first planarization layer PLN1 and the second planarization layer PLN2, but is not limited thereto.

The display panel may include a first metal pattern MP1 and a second metal pattern MP2, which form various electrodes or lines. For example, the first metal pattern MP1 may be disposed in the first metal layer ML1, and the second metal pattern MP2 may be disposed in the second metal layer ML2, but it is not limited thereto.

Referring to FIG. 18, a first metal wall 1700a, which is disposed at the boundary between the black planarization layer BPLN and the non-black planarization layer PLN, may include a first lower metal wall 1810 and a first upper metal wall 1820.

The first lower metal wall 1810 may be disposed in the first metal layer ML1. The first upper metal wall 1820 may be disposed in the second metal layer ML2.

For example, the first lower metal wall 1810 and the first upper metal wall 1820 may be a metal pattern like the first metal pattern MP1 and the second metal pattern MP2, to which an electrical signal is applied.

In another example, the first lower metal wall 1810 and the first upper metal wall 1820 may be floating patterns, to which an electrical signal is not applied, unlike the first metal pattern MP1 and the second metal pattern MP2.

For example, the first lower metal wall 1810 may include the same metal as that of a source electrode or a drain electrode of a transistor (see FIG. 7).

The first upper metal wall 1820 may include the same metal as a connection electrode RE that electrically connects the source electrode or the drain electrode of the transistor with a pixel electrode PE (see FIG. 7).

The pixel electrode PE may be disposed on the second planarization layer PLN2.

A bank BK may be disposed on the pixel electrode PE.

The bank BK may include a bank hole, through which a portion of the pixel electrode PE may be exposed. That is, the bank hole formed in the bank BK may overlap a portion of the pixel electrode PE.

For example, the bank BK may be a black bank.

If the bank BK is implemented as a black bank, contrast degradation in an organic light emitting display device may be prevented even when external light is bright.

An intermediate layer may be disposed on the bank BK, and the intermediate layer may be in contact with a portion of the pixel electrode PE through the bank hole. An emission layer EML may be included in the intermediate layer.

The emission layer EML may be disposed in a light emitting area of each of a plurality of subpixels SP.

A patterning layer MPL may be disposed on the planarization layer PLN in order to form a common electrode hole CH, to pattern the common electrode CE.

The patterning layer MPL may include a cathode patterning material for a common electrode. For example, if the common electrode CE is a cathode, the patterning material included in the patterning layer MPL may be a cathode patterning material. For example, the patterning layer MPL may include fluorine-based compound or an organic material.

The thickness of the common electrode CE may be equal to or less than that of the patterning layer MPL.

An encapsulation layer ENCAP may serve to prevent external moisture or oxygen from penetrating the light emitting device. In particular, the encapsulation layer ENCAP may prevent moisture or oxygen from penetrating the intermediate layer EL, which may include organic layers. The encapsulation layer ENCAP may be configured as a single layer or a multi-layer structure.

The display panel according to embodiments of the present disclosure may include a touch sensor layer TSL formed on the encapsulation layer ENCAP.

The touch sensor layer TSL may include touch sensor metals TSM and bridge metals BRG, and may further include one or more insulating layers such as a sensor buffer layer S-BUF, a sensor interlayer insulating layer S-ILD and a sensor protection layer S-PAC.

The sensor protection layer S-PAC may be disposed while covering the touch sensor metals TSM and bridge metals BRG.

A color filter layer CFL may be disposed on the touch sensor layer TSL.

The color filter layer CFL may include a color filter CF and black matrix BM.

When white light passes through the color filter, light of a desired color may be generated.

The color filter CF may include a first color filter configured to generate light of a first color, a second color filter configured to generate light of a second color, and a third color filter configured to generate light of a third color. The first color, the second color, and the third color may be different colors from one another and may include various colors. For example, the first color, the second color, and the third color may include red, green, and blue.

The black matrix BM may be disposed at the boundaries between the color filters.

In addition, the black matrix BM may prevent light leakage from the backlight, color mixing between subpixels, or an increase in leakage current of the transistor caused by an external light source.

The black matrix BM may include carbon black as a material.

A cover glass CG may be disposed on the color filter layer CFL.

The cover glass CG may protect a display device or a display panel.

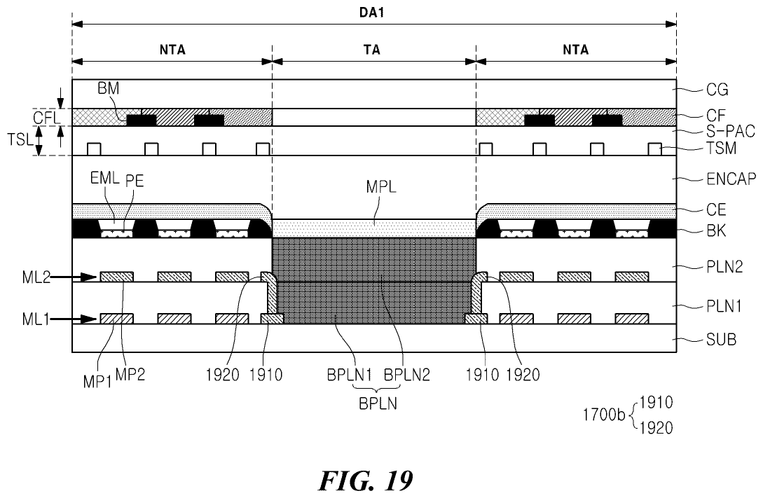

In FIGS. 19 to 21, the layered structure, except for the metal wall 1700, is the same as the layered structure in FIG. 18, and thus descriptions of the identical layers may be omitted.

Referring to FIG. 19, a second metal wall 1700b, which disposed at the boundary between the black planarization layer BPLN and the non-black planarization layer PLN, may include a second lower metal wall 1910 and a second upper metal wall 1920.

The second upper metal wall 1920 may be connected to the second lower metal wall 1910 through a hole in the first planarization layer PLN1. A first metal layer ML1 may be a metal layer located below the first planarization layer PLN1. A second metal layer ML2 may be a metal layer disposed between the first planarization layer PLN1 and the second planarization layer PLN2.

The second lower metal wall 1910 may be disposed in the first metal layer ML1. The second upper metal wall 1920 may be disposed in the second metal layer ML2.

The second upper metal wall 1920 may be disposed on the first planarization layer PLN1, and may extend to the upper surface of the second lower metal wall 1910 between the side surface of the first planarization layer PLN1 and the side surface of the first black planarization layer BPLN1.

The second lower metal wall 1910 may include the same material as a source electrode or a drain electrode of a transistor, and the second upper metal wall 1920 may include the same metal as a connection electrode RE that electrically connects the source electrode or the drain electrode of the transistor with a pixel electrode PE (see FIG. 7).

For example, the second lower metal wall 1910 and the second upper metal wall 1920 may be a metal pattern, to which an electrical signal is applied.

In another example, the second lower metal wall 1910 and the second upper metal wall 1920 may be floating patterns, to which an electrical signal is not applied.

In FIG. 19, the second lower metal wall 1910 and the second upper metal wall 1920 are illustrated as being formed separately. However, this is merely an example for the convenience of explanation, and they may also be formed as a single integrated structure.

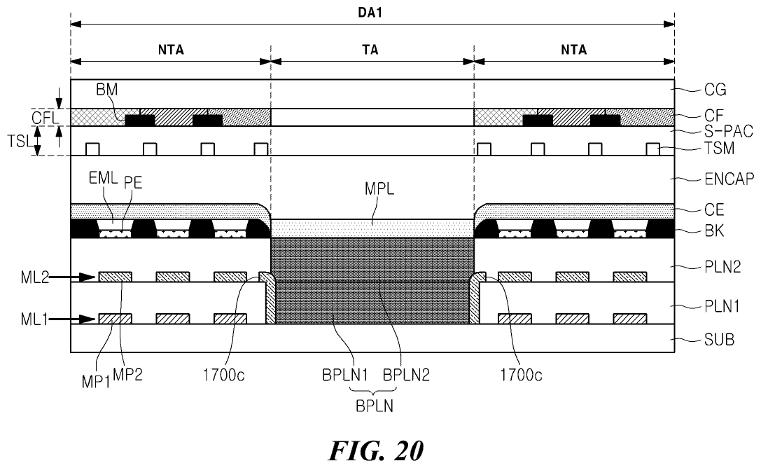

Referring to FIG. 20, a third metal wall 1700c, which is disposed at the boundary between a black planarization layer BPLN and a non-black planarization layer PLN, may be disposed on a first planarization layer PLN1, and may extend between the side surface of the first planarization layer PLN1 and the side surface of a first black planarization layer BPLN1.

The third metal wall 1700c may include the same metal as a connection electrode RE that electrically connects a source electrode or a drain electrode of a transistor with a pixel electrode PE (see FIG. 7)

For example, the third metal wall 1700c may be a metal pattern, to which an electrical signal is applied.

In another example, the third metal wall 1700c may be floating patterns, to which an electrical signal is not applied.

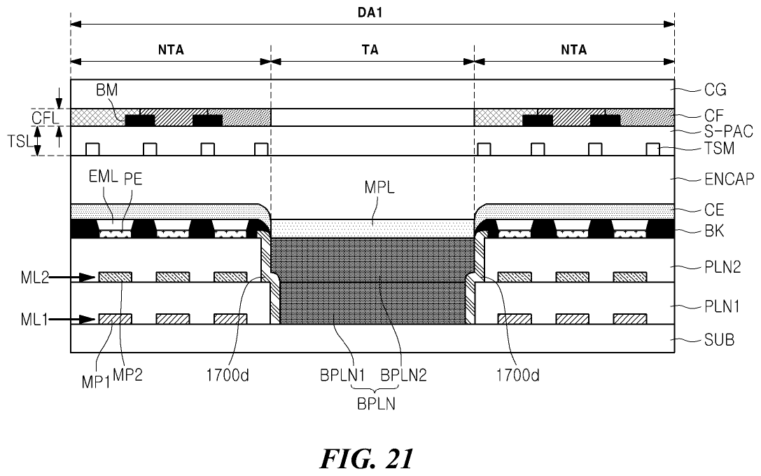

Referring to FIG. 21, a first metal layer ML1 may be a metal layer located below the first planarization layer PLN1.

A second metal layer ML2 may be a metal layer disposed between the first planarization layer PLN1 and a second planarization layer PLN2.

A third metal layer may be a metal layer on the second planarization layer PLN2.

A third metal layer may be a metal layer in which a pixel electrode PE is disposed.

A fourth metal wall 1700d may be disposed in the third metal layer on the second planarization layer PLN2.

The fourth metal wall 1700d may include the same metal as the pixel electrode PE.

The fourth metal wall 1700d may extend between the side surface of the second planarization layer PLN2 and the side surface of a second black planarization layer BPLN2, and between the side surface of the first planarization layer PLN1 and the side surface of the first black planarization layer BPLN1.

For example, the fourth metal wall 1700d may be a metal pattern, to which an electrical signal is applied.

In another example, the fourth metal wall 1700d may be floating patterns, to which an electrical signal is not applied.

The second metal wall 1700b, the third metal wall 1700c, and the fourth metal wall 1700d described above may be disposed in the edge region of the transmissive area TA, and may be arranged to vertically cover the boundary of the transmissive area TA. By doing so, light incident on the transmissive area TA may be guided toward the first electronic device 11 which may correspond to an infrared sensor. Accordingly, the light reception efficiency of the first electronic device 11 disposed below a substrate SUB may be improved.

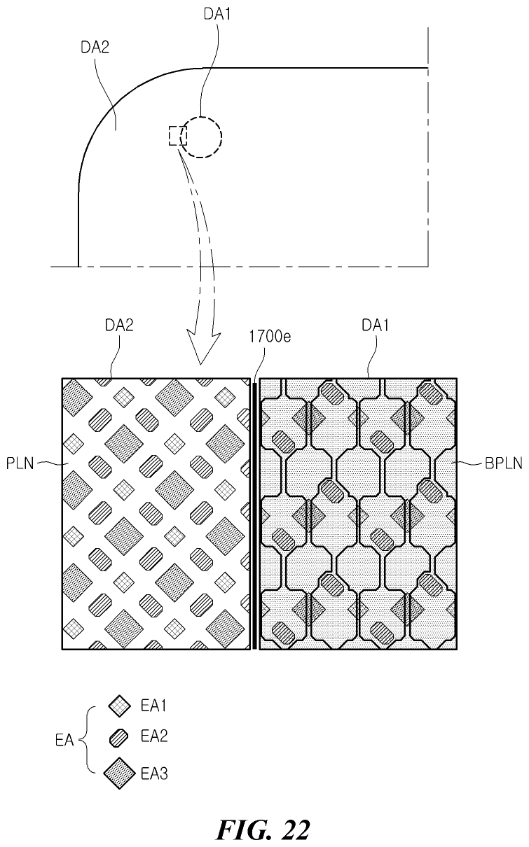

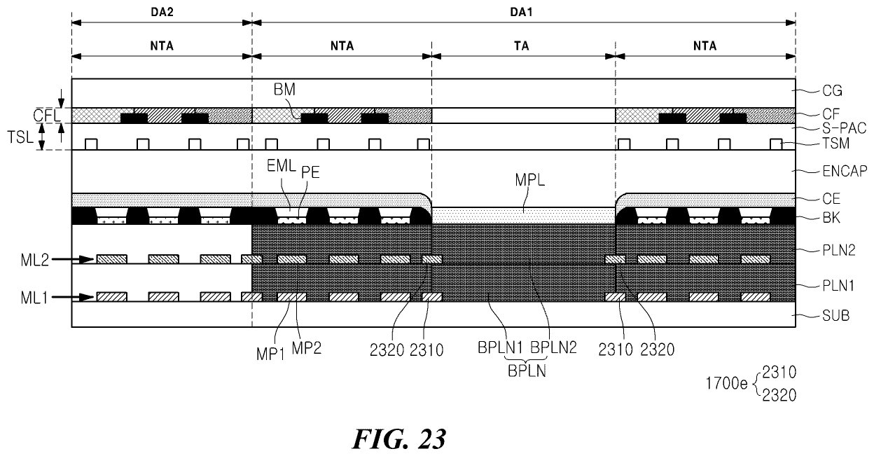

FIGS. 22 and 23 are an example plan view and a simplified cross-sectional view of a first display area DA1 and a second display area DA2 in a display panel according to embodiments of the present disclosure.

Referring to FIGS. 22 and 23, a fifth metal wall 1700e may be disposed at the boundary between the first display area DA1, in which a black planarization layer BPLN is disposed, and the second display area DA2, in which a non-black planarization layer PLN is disposed. That is, the black planarization layer BPLN may be disposed along the edge of the first display area DA1. The black planarization layer BPLN may overlap a first electronic device 11.

In FIG. 23, the layered structure, except for the fifth metal wall 1700e, is the same as the layered structure in FIG. 18, and thus descriptions of the identical layers may be omitted.

Referring to FIG. 23, the fifth metal wall 1700e, which is disposed at the boundary between the black planarization layer BPLN and the non-black planarization layer PLN, may include a fifth lower metal wall 2310 and a fifth upper metal wall 2320.

The fifth lower metal wall 2310 may be disposed in a first metal layer ML1. The fifth upper metal wall 2320 may be disposed in a second metal layer ML2.

The fifth metal wall 1700e may be formed as a first metal pattern MP1 and a second metal pattern MP2, which are disposed on the first planarization layer PLN1 and the second planarization layer PLN2, respectively. That is, the fifth lower metal wall 2310 may correspond to a type of the first metal pattern MP1, and the fifth upper metal wall 2320 may correspond to a type of the second metal pattern MP2.

For example, the fifth lower metal wall 2310 may include the same metal as a source electrode or a drain electrode of a transistor.

For example, the fifth upper metal wall 2320 may include the same metal as a connection electrode RE that electrically connects the source electrode or the drain electrode of the transistor with a pixel electrode PE (see FIG. 7)

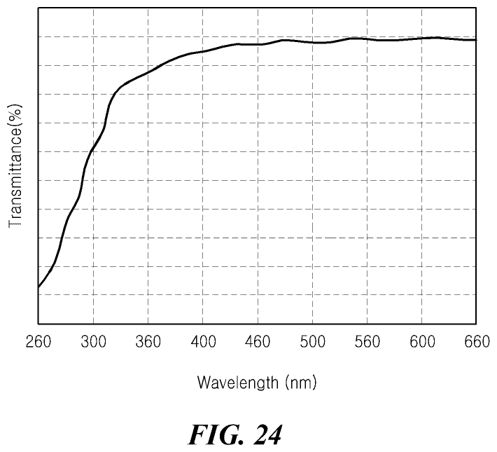

FIG. 24 illustrates a light transmittance of a display panel as a function of the wavelength of light passing through a first display area where a planarization layer comprising photoacrylic is disposed.

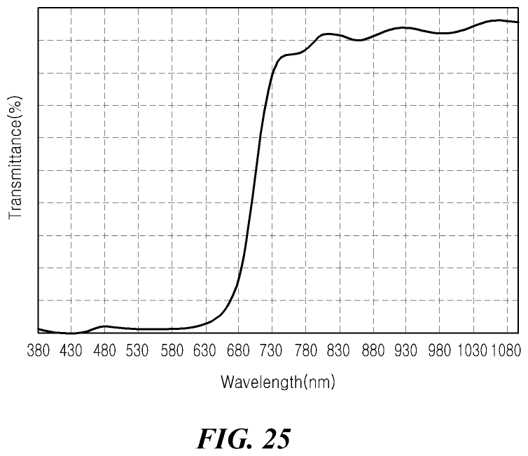

FIG. 25 illustrates the light transmittance of a display panel as a function of the wavelength of light passing through a first display area where a black planarization layer according to embodiments of the present disclosure is disposed.

Usually, a planarization layer having planarization and insulating functions may be formed of photoacyrlic and the like. A black planarization layer according to embodiments of the present disclosure may be composed of a material that provides not only planarization function but also an out-gassing prevention function. For example, the black planarization layer can include lactam black as a material.

Referring to FIGS. 24 and 25, the transmittance of visible light (380 nm to 780 nm) in the first display area where the black planarization layer including lactam black is disposed is significantly lower than that of the first display area where non-black planarization layer including photoacrylic is disposed. As a result, the first electronic device 11, which may correspond to an infrared sensor, may receive light having a lower proportion of visible light and a higher proportion of infrared light. Accordingly, the first electronic device 11 may perform a precise sensing function by utilizing high-purity infrared light.

Accordingly, the difference between the infrared transmittance and the visible light transmittance in a transmissive area where the black planarization layer BPLN is disposed may be greater than that of the first display area where a planarization layer composed of photoacrylic is disposed.

Accordingly, by disposing the black planarization layer in a region overlapping the infrared sensor, it is possible to provide a display device having a light transmission structure that allows the infrared sensor disposed under the display panel to normally receive light, by minimizing transmittance in the visible light region and maximizing transmittance in the long-wavelength region.

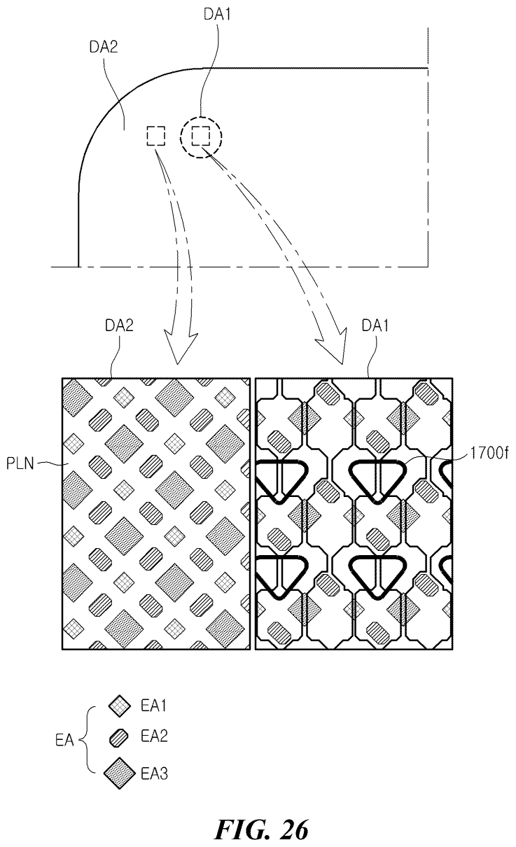

FIG. 26 is an example plan view of a first display area DA1 and a second display area DA2 in a display panel according to embodiments of the present disclosure.

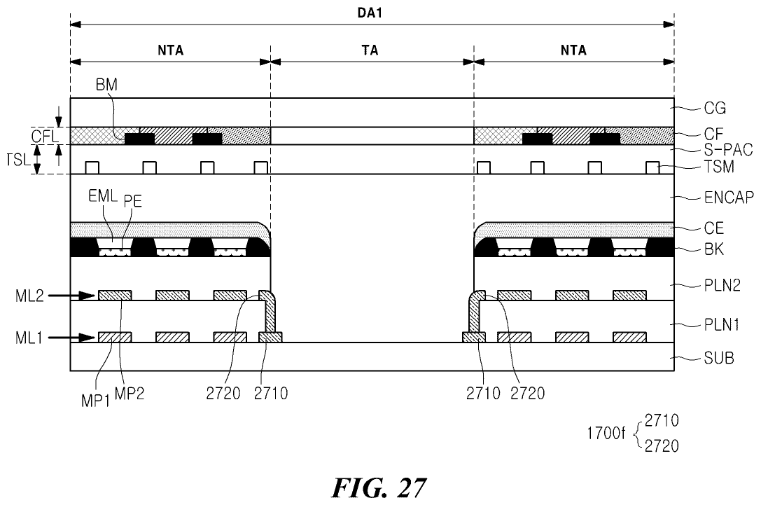

FIG. 27 is an example simplified cross-sectional view of a first display area DA1 in a display panel according to embodiments of the present disclosure.

Referring to FIG. 27, the first display area DA1 may include: a pixel electrode PE on a substrate SUB; an emission layer EML on the pixel electrode PE; a common electrode CE disposed on the emission layer EML and having a plurality of holes disposed in a transmissive area TA; and a planarization layer PLN disposed between the substrate SUB and the pixel electrode PE and having openings overlapping the plurality of holes.

By disposing an opening of the planarization layer in the transmissive area TA, out-gassing that may occur in the planarization layer PLN overlapping the transmissive area TA due to ultraviolet irradiation can be fundamentally prevented.

A sixth metal wall 1700f may be disposed along a side surface of the opening of the planarization layer PLN.

Referring to FIG. 27, the sixth metal wall 1700f, which is disposed at the boundary between the planarization layer PLN and the opening, may include a sixth lower metal wall 2710 and a sixth upper metal wall 2720.

The sixth lower metal wall 2710 may be disposed in a first metal layer ML1. The sixth upper metal wall 2720 may be disposed in a second metal layer ML2.

The sixth upper metal wall 2720 may be disposed on a first planarization layer PLN1 and may extend to an upper surface of the sixth lower metal wall 2710 between a side surface of the first planarization layer PLN1 and a side surface of the opening.

The sixth lower metal wall 2710 may include the same material as a source electrode or a drain electrode of a transistor, and the sixth upper metal wall 2720 may include the same material as a connection electrode RE that electrically connects the source electrode or the drain electrode of the transistor with a pixel electrode PE (see FIG. 7).

In FIG. 27, the sixth lower metal wall 2710 and the sixth upper metal wall 2720 are illustrated as being formed separately. However, this is merely an example for the convenience of explanation, and they may also be formed as a single integrated structure.

The shape of the sixth metal wall 1700f may guide light toward the infrared sensor overlapping the transmissive area TA, thereby helping the infrared sensor disposed under the substrate SUB efficiently receive light.

The embodiments of the present disclosure described above may provide a display device having a light transmission structure that allows a sensing sensor disposed below the display panel to normally receive light, while preventing an electronic component from being exposed on the front surface of the display device.

The embodiments of the present disclosure provides a display device including a substrate including a display area formed on the substrate and configured to display an image, the display area including a first display area having a transmissive area and a first non-transmissive area that comprises a plurality of light emitting areas, and a second display area having a second non-transmissive area and disposed outside the first display area, a pixel electrode disposed in the first display area on the substrate, an emission layer disposed on the pixel electrode, a common electrode disposed on the emission layer and having a plurality of holes located in the transmissive area, and a black planarization layer disposed between the substrate and the pixel electrode, and located in an entire or partial portion of the first display area.

In one or more aspects, the display device may include the black planarization layer overlapping the plurality of holes disposed in the transmissive area.

In one or more aspects, the display device may include the black planarization layer disposed in the first display area.

In one or more aspects, the display device may include the black planarization layer disposed in the first display area and the second display area.

In one or more aspects, the display device may further include a black bank disposed on a pixel electrode, the black bank having a first opening overlapping the transmissive area and a second opening overlapping a portion of the pixel electrode. The first opening may overlap the black planarization layer.

In one or more aspects, the display device may include the black planarization layer formed by an inkjet printing process.

In one or more aspects, the display device may include the black planarization layer including lactam black as a material.

In one or more aspects, the display device may include a color filter layer disposed on the common electrode, and the color filter layer may include a black matrix.

In one or more aspects, the display device may include a black matrix and a black planarization layer formed of different materials.

In one or more aspects, the display device may include the black planarization layer disposed in the transmissive area, and a non-black planarization layer disposed between the substrate and the pixel electrode in another area.

In one or more aspects, the display device may include the black planarization layer disposed in the first display area, and a non-black planarization layer disposed between the substrate and the pixel electrode in another area.

In one or more aspects, the display device may include the black planarization layer having a greater transmittance difference between infrared and visible light than that of the non-black planarization layer.

In one or more aspects, the display device may further include a metal wall located at a boundary between the black planarization layer and the non-black planarization layer.

In one or more aspects, the display device may include an infrared sensor disposed beneath the substrate and overlapping the first display area.

In one or more aspects, the display device may include the non-black planarization layer disposed in a third display area, in which the black planarization layer is not disposed.

The embodiments of the present disclosure provides a display device including a substate including a display area formed on the substrate and configured to display an image, the display area including a first display area having a transmissive area and a first non-transmissive area that comprises a plurality of light emitting areas, and a second display area having a second non-transmissive area and disposed outside the first display area, a pixel electrode disposed in the first display area on the substrate, an emission layer disposed on the pixel electrode, a common electrode disposed on the emission layer and having a plurality of holes located in the transmissive area, and a planarization layer disposed between the substrate and the pixel electrode. The planarization layer may include a first part disposed in an entire or partial region of the first display area, and a second part different from the first part. The first part and the second part may include different materials.

The embodiments of the present disclosure provides a display device including a substrate including a display area formed on the substrate and configured to display an image, the display area including a first display area having a transmissive area and a first non-transmissive area that comprises a plurality of light emitting areas, and a second display area having a second non-transmissive area and disposed outside the first display area, a pixel electrode disposed in the first display area on the substrate, an emission layer disposed on the pixel electrode, a common electrode disposed on the emission layer and having a plurality of holes located in the transmissive area, and a planarization layer disposed between the substrate and the pixel electrode. The planarization layer may include openings overlapping the plurality of holes.

In one or more aspects, the display device may include a metal wall disposed at the boundary of the openings of the planarization layer.

According to one or more embodiments of the present disclosure, a display device may prevent degradation in image quality that may occur due to a structure for improving light transmittance.

According to one or more embodiments of the present disclosure, a display device may be provided that prevents pixel shrinkage even when exposed to ultraviolet light.

According to one or more embodiments of the present disclosure, a display device may be provided that prevents image quality degradation in a sensor area even when exposed to ultraviolet light.

According to one or more embodiments of the present disclosure, a display device may be provided that prevents pixel shrinkage even when exposed to ultraviolet light, thereby enabling the light emitting device to have a longer lifespan and operate at lower power.

The above description has been presented to enable any person skilled in the art to make, use and practice the technical features of the present disclosure, and has been provided in the context of a particular application and its requirements as examples. Various modifications, additions and substitutions to the described embodiments will be readily apparent to those skilled in the art, and the principles described herein may be applied to other embodiments and applications without departing from the scope of the present disclosure. The above description and the accompanying drawings provide examples of the technical features of the present disclosure for illustrative purposes only. That is, the disclosed embodiments are intended to illustrate the scope of the technical features of the present disclosure.

### DESCRIPTION OF REFERENCE NUMERALS

100: Display device
110: Display panel
11: First electronic device
12: Second electronic device
220: Data driving circuit
230: Gate driving circuit
240: Display controller
250: Host system
260: Touch driving circuit
270: Touch controller
700: Electronic device
1700: Metal wall
1700a: First metal wall
1700b: Second metal wall
1700c: Third metal wall
1700d: Fourth metal wall
1700e: Fifth metal wall
1700f: Sixth metal wall
1810: First lower metal wall
1820: First upper metal wall
1910: Second lower metal wall
1920: Second upper metal wall
2310: Fifth lower metal wall
2320: Fifth upper metal wall
2710: Sixth lower metal wall
2720: Sixth upper metal wall

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate including a display area on the substrate and configured to display an image, the display area comprising:
a first display area including a transmissive area and a first non-transmissive area comprising a plurality of light emitting areas, and
a second display area including a second non-transmissive area and disposed outside the first display area;
a pixel electrode disposed in the first display area on the substrate;
an emission layer on the pixel electrode;
a common electrode on the emission layer and having a plurality of holes located in the transmissive area; and
a black planarization layer between the substrate and the pixel electrode, and located in an entire or partial portion of the first display area.

2. The display device of claim 1, wherein the black planarization layer overlaps the plurality of holes located in the transmissive area.

3. The display device of claim 1, wherein the black planarization layer is disposed over an entire region of the first display area.

4. The display device of claim 3, wherein the black planarization layer further extends into the second display area.

5. The display device of claim 1, further comprising a black bank on the pixel electrode and comprising:
a first opening overlapping the transmissive area; and
a second opening overlapping at least a part of the pixel electrode,
wherein the first opening overlaps the black planarization layer.

6. The display device of claim 1, wherein the black planarization layer is formed by an inkjet printing process.

7. The display device of claim 1, wherein the black planarization layer includes lactam black.

8. The display device of claim 1, further comprising a color filter layer on the common electrode,
wherein the color filter layer includes a color filter and a black matrix, and
wherein the black matrix is made of a different material from that of the black planarization layer.

9. The display device of claim 1, further comprising a non-black planarization layer between the substrate and the pixel electrode,
wherein the black planarization layer is located in a first region, and
wherein the non-black planarization layer is located in a second region different from the first region.

10. The display device of claim 9, wherein the first region is one of the transmissive areas and the first display area.

11. The display device of claim 9, wherein a difference between infrared transmittance and visible light transmittance of the black planarization layer is greater than that of the non-black planarization layer.

12. The display device of claim 9, further comprising a metal wall located at a boundary between the first region and the second region.

13. The display device of claim 1, further comprising an infrared sensor under the substrate, overlapping the first display area.

14. The display device of claim 1, further comprising:
a third display area different from the first display area and the second display area; and
a non-black planarization layer disposed in the third display area,
wherein the black planarization layer is not disposed in the third display area.

15. A display device comprising:
a substrate including a display area on the substrate and configured to display an image, the display area comprising:
a first display area including a transmissive area and a first non-transmissive area comprising a plurality of light emitting areas, and
a second display area including a second non-transmissive area and disposed outside the first display area;
a pixel electrode disposed in the first display area on the substrate;
an emission layer on the pixel electrode;
a common electrode on the emission layer and having a plurality of holes located in the transmissive area; and
a planarization layer between the substrate and the pixel electrode,
wherein the planarization layer comprises:
a first part disposed in an entire or partial region of the first display area, and
a second part different from the first part,
wherein the first part and the second part include different materials.

16. The display device of claim 15, wherein the first part is one of the transmissive areas and the first display area.

17. The display device of claim 15, wherein the first part includes lactam black.

18. A display device comprising:
a substrate including a display area on the substrate and configured to display an image, the display area comprising:
a first display area including a transmissive area and a first non-transmissive area comprising a plurality of light emitting areas, and
a second display area including a second non-transmissive area and disposed outside the first display area;
a pixel electrode disposed in the first display area on the substrate;
an emission layer on the pixel electrode;
a common electrode on the emission layer and having a plurality of holes located in the transmissive area; and
a planarization layer between the substrate and the pixel electrode,
wherein the planarization layer includes openings overlapping the plurality of holes.

19. The display device of claim 18, further comprising a metal wall disposed at a side surface of the openings.

20. The display device of claim 18, wherein the openings are aligned with at least one hole in the common electrode.
